(19) United States
(12) Patent Application Publication
(10) Pub. No.: US 2025/0096087 A1
(43) Pub. Date: Mar. 20, 2025

(54) SEMICONDUCTOR PACKAGE AND ELECTRONIC DEVICE

(71) Applicant: SONY SEMICONDUCTOR SOLUTIONS CORPORATION, Kanagawa (JP)

(72) Inventors: Hirohisa YASUKAWA, Kanagawa (JP); Koichi IGARASHI, Kanagawa (JP); Hiroyuki SHIGETA, Kanagawa (JP); Hikaru OHIRA, Kanagawa (JP); Kiyohisa SAKAI, Kanagawa (JP); Kohyoh HOSOKAWA, Kanagawa (JP)

(73) Assignee: SONY SEMICONDUCTOR SOLUTIONS CORPORATION, Kanagawa (JP)

(21) Appl. No.: 18/561,820

(22) PCT Filed: Dec. 28, 2021
(86) PCT No.: PCT/JP2021/048934

§ 371 Date: Nov. 17, 2023

(30) Foreign Application Priority Data
May 25, 2021 (JP) 2021-087821

(51) Int. Cl. H01L 23/498; H01L 23/00; H01L 23/31

(52) U.S. Cl. CPC H01L 23/49816; H01L 23/3135; H01L 23/49838; H01L 24/08; H01L 24/69; H01L 2224/08113; H01L 2224/69

(57) ABSTRACT

To improve reliability by securing drop test characteristics or impact resistance in a semiconductor package. A semiconductor package includes a plurality of insulating layers and an under bump metal layer. The under bump metal layer is a metal layer connected to a bump. The under bump metal layer is partially exposed at the opening of the outermost layer among the plurality of insulating layers, and is connected to the bump at the exposed portion. The diameter of the under bump metal layer is larger than the diameter of the opening of the outermost layer. As a result, the under bump metal layer inhibits or reduces transmission of force to the land or RDL via the bump.

### TECHNICAL FIELD

The present technology relates to a semiconductor package. Specifically, the present invention relates to a semiconductor package including an under bump metal layer and an electronic device including the semiconductor package.

### BACKGROUND ART

Conventionally, for connecting a bump to a semiconductor package, a structure in which the bump is connected to a wiring layer via an under bump metal layer is known. In such an under bump metal layer, when a force is applied in the substrate planar direction in a drop test, the force is transmitted along the interface between the under bump metal layer and the insulating layer via the bump and the under bump metal layer, and there is a risk that a crack occurs in the wiring layer. Therefore, a structure has been proposed in which a recess is provided under the under bump metal layer to reduce the transmitted force (see, for example, Patent Document 1).

### CITATION LIST

### Patent Document

PATENT DOCUMENT 1 US Patent Application Publication No. 2018/076151 Specification

### SUMMARY OF THE INVENTION

### Problems to be Solved by the Invention

In the above-described conventional technique, the crack propagation path is lengthened to reduce the propagated force. However, in such a structure, since a force is transmitted to the under bump metal layer via the bump, it is necessary to process the structure into a complicated shape in order to absorb the force, and there is a problem that the manufacturing process becomes complicated.

The present technology has been made in view of such a situation, and an object thereof is to improve reliability by securing drop test characteristics or impact resistance in a semiconductor package.

### Solutions to Problems

The present technology has been made to solve the above-described problems, and a first aspect thereof is a semiconductor package and an electronic device including: a plurality of insulating layers; and an under bump metal layer that is partially exposed at an opening of an outermost layer among the plurality of insulating layers and is connected to a bump, in which a diameter of the under bump metal layer is larger than a diameter of the opening. This brings about an effect of suppressing a force transmitted from the under bump metal layer to the land, the redistribution layer, or the like via the bump.

Furthermore, in the first aspect, at least one redistribution layer connected to the under bump metal layer may be further provided. In this case, the diameter of the under bump metal layer is desirably larger than the diameter of the land in the redistribution layer connected to the under bump metal layer. This brings about an effect of improving the wiring density between the bumps. Further, it is desirable that a part of the redistribution layer is disposed to overlap immediately below the under bump metal layer. This brings about an effect of arranging a larger number of redistribution layers.

Furthermore, in the first aspect, the under bump metal layer may include a protrusion at an interface with the bump. This brings about an effect of strengthening the connection between the under bump metal layer and the bump. In this case, the protrusion may have a predetermined planar shape. In addition, the protrusion may have a column shape having a reverse taper relative to the bump.

In addition, the first aspect may further include a resin that covers at least a part of a connection portion between a plurality of the under bump metal layer and the bump arranged two-dimensionally. This brings about an effect of enhancing the connection of the bumps and reducing distortion concentrated on the bump base portion of the package corner or the like. In this case, the resin may be formed at four corners of the predetermined region, or may be formed at an outer peripheral portion of the predetermined region.

Furthermore, in the first aspect, the bump may have an oval coin planar shape in at least a part of a connection portion between a plurality of the under bump metal layer and the bump arranged two-dimensionally. This brings about an effect of alleviating the stress of the chip. In this case, the bump having the oval coin planar shape may be formed at four corners of a predetermined region, or may be formed at an outer peripheral portion of a predetermined region. In addition, the bump having the oval coin planar shape may have an inclination that radially spreads in a predetermined region, and may further include a metal column bump at a connection portion with the under bump metal layer.

Furthermore, in the first aspect, the bump may have a height higher than that of other bumps at four corners or an outer peripheral portion of a predetermined region. This provides an effect of enhancing the stress resistance and improving the resistance of the mounting reliability as a package.

Furthermore, in the first aspect, the bump may have a diameter larger than that of other bumps at four corners or an outer peripheral portion of a predetermined region. This provides an effect of enhancing the stress resistance and improving the resistance of the mounting reliability as a package.

Furthermore, in the first aspect, the under bump metal layer may include a protrusion at an interface with an insulating layer facing a lower portion of the under bump metal layer among the plurality of insulating layers. This brings about an effect of improving impact resistance.

Furthermore, in the first aspect, the under bump metal layer may include a protrusion at an interface with the outermost layer among the plurality of insulating layers. As a result, the adhesion between the under bump metal layer and the insulating layer as the outermost layer is improved, so that the mounting reliability is improved.

In addition, in the first aspect, a cushion pad having an overhanging shape may be further provided between the bump and the under bump metal layer. This brings about an effect of diffusing the thermal stress into the insulating layer on the surface layer to diffuse the stress. In this case, the cushion pad may include an uneven portion on the surface. As a result, by having more overhanging shapes, there is an effect of efficiently diffusing stress.

Furthermore, in the first aspect, the under bump metal layer may have a tapered shape having a first curvature radius. This brings about an effect of suppressing stress concentration in the via corner portion in the substrate mounted state.

Furthermore, in the first aspect, a metal column connecting the under bump metal layer and the redistribution layer and having a tapered shape having a second curvature radius may be further provided. This brings about an effect of suppressing the stress concentration in accordance with the stress concentration point.

### BRIEF DESCRIPTION OF DRAWINGS

FIG. 1 is a cross-sectional view illustrating a first example of a semiconductor package according to a first embodiment of the present technology.

FIG. 2 is a plan view illustrating the first example of the semiconductor package according to the first embodiment of the present technology.

FIG. 3 is a cross-sectional view illustrating a second example of the semiconductor package according to the first embodiment of the present technology.

FIG. 4 is a first view illustrating a manufacturing process example of the second example of the semiconductor package according to the first embodiment of the present technology.

FIG. 5 is a second view illustrating a manufacturing process example of the second example of the semiconductor package according to the first embodiment of the present technology.

FIG. 6 is a cross-sectional view illustrating a third example of the semiconductor package according to the first embodiment of the present technology.

FIG. 7 is a cross-sectional view illustrating a fourth example of the semiconductor package according to the first embodiment of the present technology.

FIG. 8 is a cross-sectional view illustrating a fifth example of the semiconductor package according to the first embodiment of the present technology.

FIG. 9 is a cross-sectional view illustrating a sixth example of the semiconductor package according to the first embodiment of the present technology.

FIG. 10 is a cross-sectional view illustrating a structural example of a semiconductor package according to a second embodiment of the present technology.

FIG. 11 is a plan view illustrating an arrangement example of the protrusions 410 according to the second embodiment of the present technology.

FIG. 12 is a plan view illustrating a shape example of the protrusion 410 according to the second embodiment of the present technology.

FIG. 13 is a first view illustrating a manufacturing process example of the protrusion 410 according to the second embodiment of the present technology.

FIG. 14 is a second view illustrating a manufacturing process example of the protrusion 410 according to the second embodiment of the present technology.

FIG. 15 is a cross-sectional view illustrating a modification of the protrusion shape according to the second embodiment of the present technology.

FIG. 16 is a cross-sectional view illustrating a structural example of a semiconductor package according to a third embodiment of the present technology.

FIG. 17 is a plan view illustrating an arrangement example of the resin 499 according to the third embodiment of the present technology.

FIG. 18 is a first view illustrating a first example of the process of forming the resin 499 according to the third embodiment of the present technology.

FIG. 19 is a second view illustrating the first example of the process of forming the resin 499 according to the third embodiment of the present technology.

FIG. 20 is a first view illustrating a second example of the process of forming the resin 499 according to the third embodiment of the present technology.

FIG. 21 is a second view illustrating the second example of the process of forming the resin 499 according to the third embodiment of the present technology.

FIG. 22 is a cross-sectional view illustrating a first example of a structure of a semiconductor package according to a fourth embodiment of the present technology.

FIG. 23 is a plan view illustrating a first arrangement example of the bumps 490 according to the fourth embodiment of the present technology.

FIG. 24 is a plan view illustrating a second arrangement example of the bumps 490 according to the fourth embodiment of the present technology.

FIG. 25 is a plan view illustrating a third arrangement example of the bumps 490 according to the fourth embodiment of the present technology.

FIG. 26 is a plan view illustrating a fourth arrangement example of the bumps 490 according to the fourth embodiment of the present technology.

FIG. 27 is a plan view illustrating a fifth arrangement example of the bumps 490 according to the fourth embodiment of the present technology.

FIG. 28 is a plan view illustrating a sixth arrangement example of the bumps 490 according to the fourth embodiment of the present technology.

FIG. 29 is a first view illustrating an example of the process of forming the bump 490 of the first example according to the fourth embodiment of the present technology.

FIG. 30 is a second view illustrating an example of the process of forming the bump 490 of the first example according to the fourth embodiment of the present technology.

FIG. 31 is a cross-sectional view illustrating a second example of the structure of the semiconductor package according to the fourth embodiment of the present technology.

FIG. 32 is a first view illustrating an example of the process of forming the copper pillar bump 493 of the second example according to the fourth embodiment of the present technology.

FIG. 33 is a second view illustrating an example of the process of forming the copper pillar bump 493 of the second example according to the fourth embodiment of the present technology.

FIG. 34 is a cross-sectional view illustrating a first example of a structure of a semiconductor package according to a fifth embodiment of the present technology.

FIG. 35 is a plan view illustrating the first example of the structure of the semiconductor package according to the fifth embodiment of the present technology.

FIG. 36 is another plan view illustrating the first example of the structure of the semiconductor package according to the fifth embodiment of the present technology.

FIG. 37 is a first view illustrating an example of a bump forming process of the first example according to the fifth embodiment of the present technology.

FIG. 38 is a second view illustrating an example of a bump forming process of the first example according to the fifth embodiment of the present technology.

FIG. 39 is a cross-sectional view illustrating a second example of the structure of the semiconductor package according to the fifth embodiment of the present technology.

FIG. 40 is a plan view illustrating the second example of the structure of the semiconductor package according to the fifth embodiment of the present technology.

FIG. 41 is another plan view illustrating the second example of the structure of the semiconductor package according to the fifth embodiment of the present technology.

FIG. 42 is a cross-sectional view illustrating a first example of a structure of a semiconductor package according to a sixth embodiment of the present technology.

FIG. 43 is a cross-sectional view illustrating a second example of the structure of the semiconductor package according to the sixth embodiment of the present technology.

FIG. 44 is a cross-sectional view illustrating a first structural example of a semiconductor package according to a seventh embodiment of the present technology.

FIG. 45 is a cross-sectional view illustrating a second structural example of the semiconductor package according to the seventh embodiment of the present technology.

FIG. 46 is a cross-sectional view illustrating a modification of the cushion pad 494 according to the seventh embodiment of the present technology.

FIG. 47 is a cross-sectional view illustrating a first structural example of a semiconductor package according to an eighth embodiment of the present technology.

FIG. 48 is a cross-sectional view illustrating a second structural example of the semiconductor package according to the eighth embodiment of the present technology.

FIG. 49 is a cross-sectional view illustrating a third structural example of the semiconductor package according to the eighth embodiment of the present technology.

FIG. 50 is a first view illustrating a manufacturing process example of the semiconductor package according to the eighth embodiment of the present technology.

FIG. 51 is a second view illustrating a manufacturing process example of the semiconductor package according to the eighth embodiment of the present technology.

FIG. 52 is a third view illustrating a manufacturing process example of the semiconductor package according to the eighth embodiment of the present technology.

FIG. 53 is a fourth view illustrating a manufacturing process example of the semiconductor package according to the eighth embodiment of the present technology.

FIG. 54 is a fifth view illustrating a manufacturing process example of the semiconductor package according to the eighth embodiment of the present technology.

FIG. 55 is a perspective view illustrating an external configuration example of an electronic device 700 including a semiconductor package according to an embodiment of the present technology.

FIG. 56 is a block diagram illustrating a functional configuration example of the electronic device 700 including a semiconductor package according to an embodiment of the present technology.

### MODE FOR CARRYING OUT THE INVENTION

Hereinafter, modes for carrying out the present technology (hereinafter referred to as embodiments) will be described. The description will be given in the following order.
1. First Embodiment (Relationship Between UBM Diameter and Opening Diameter)
2. Second Embodiment (Protection of Package Base)
3. Third Embodiment (Protrusion From UBM to Bump)
4. Fourth Embodiment (Oval Coin-Shaped Bump)
5. Fifth Embodiment (Bump Size)
6. Sixth Embodiment (Protrusion From UBM to Insulating Layer)
7. Seventh Embodiment (Cushion Pad)
8. Eighth Embodiment (UBM Tapered Shape With Predetermined Curvature Radius)
9. Application Example

### 1. First Embodiment

### First Example

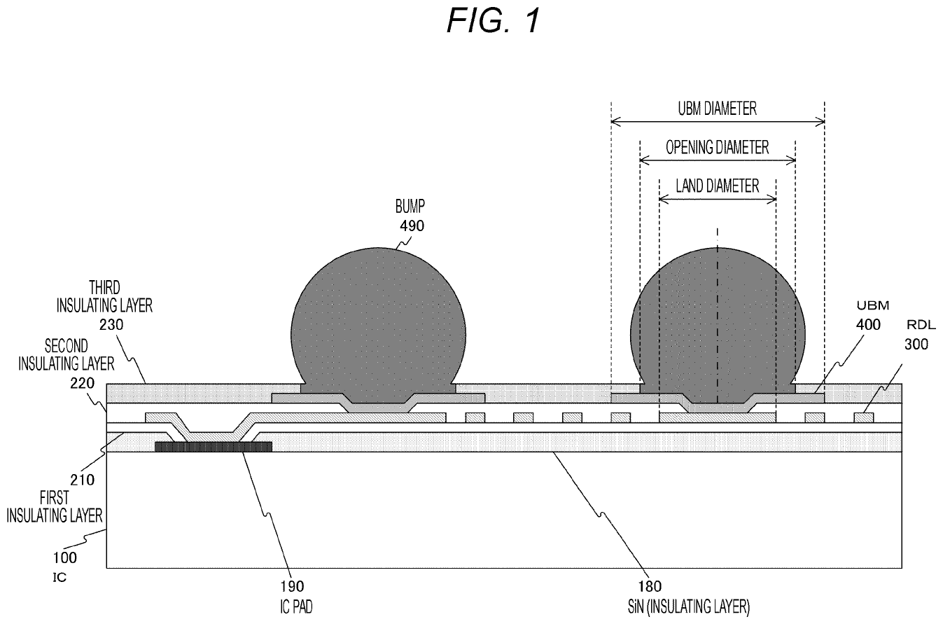

FIG. 1 is a cross-sectional view illustrating a first example of a semiconductor package according to a first embodiment of the present technology.

The first example of this semiconductor package assumes a wafer level chip size package (WLCSP). The WLCSP is a semiconductor chip package packaged in a wafer state. In addition, in the first example, one redistribution layer (RDL) is assumed.

The semiconductor package includes an integrated circuit (IC) 100 and an IC pad 190 for input and output. The IC 100 is covered with an insulating layer 180. The insulating layer 180 is constituted by, for example, a silicon nitride film (SiN).

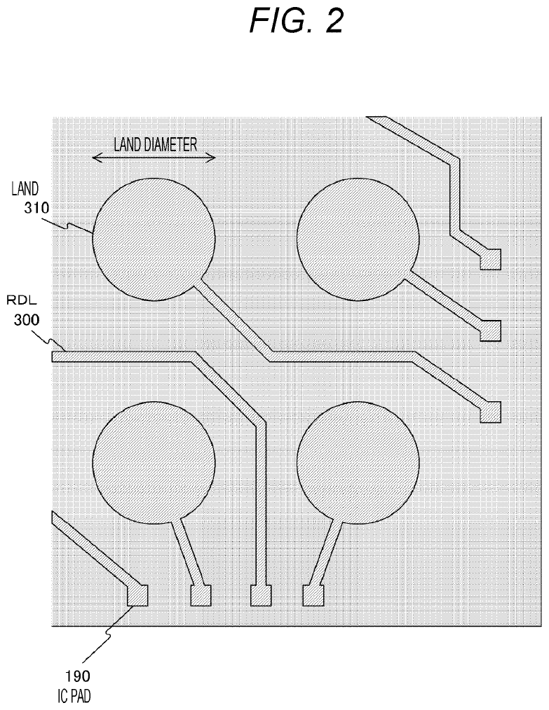

This semiconductor package includes three insulating layers 210, 220 and 230. An RDL 300 as a wiring layer is formed between the first insulating layer 210 and the second insulating layer 220. As illustrated in FIG. 2, the RDL 300 includes a land 310 connected to an under bump metal layer 400. FIG. 2 is a plan view illustrating a first example of the semiconductor package according to the first embodiment of the present technology.

The under bump metal layer (UBM) 400 is a metal layer connected to a bump 490.

The under bump metal layer 400 is formed between the second insulating layer 220 and the third insulating layer 230. The under bump metal layer 400 has a structure in which it is connected to the bump 490 at the central portion and is disposed on the second insulating layer 220 at the outer edge portion, and as a result, its cross section has an arch shape.

The bump 490 is a projecting electrode for input and output of the semiconductor package. The bump 490 is constituted by, for example, a solder ball. In order to connect the bump 490 and the under bump metal layer 400, the third insulating layer 230 as the outermost layer is provided with an opening, and has a solder mask defined (SMD) structure that covers the surface other than the opening. Therefore, the third insulating layer 230 is also referred to as a solder resist.

Here, the diameter of the under bump metal layer 400 is formed to be larger than the opening diameter of the outermost layer. As a result, the under bump metal layer 400 inhibits or reduces transmission of a force to the land 310 or the RDL 300 via the bump 490, so that the drop test characteristics and impact resistance can be improved.

In addition, the diameter of the under bump metal layer 400 is formed to be larger than the diameter of the land 310 in the RDL 300 connected to the under bump metal layer 400. As a result, the wiring density between the bumps 490 can be improved. That is, even in a case where the pitches between the under bump metal layers 400 are equal, if the diameter of the land 310 is small, a part of the RDL 300 overlaps immediately below the under bump metal layer 400, and a larger number of RDLs 300 can be wired.

### Second Example

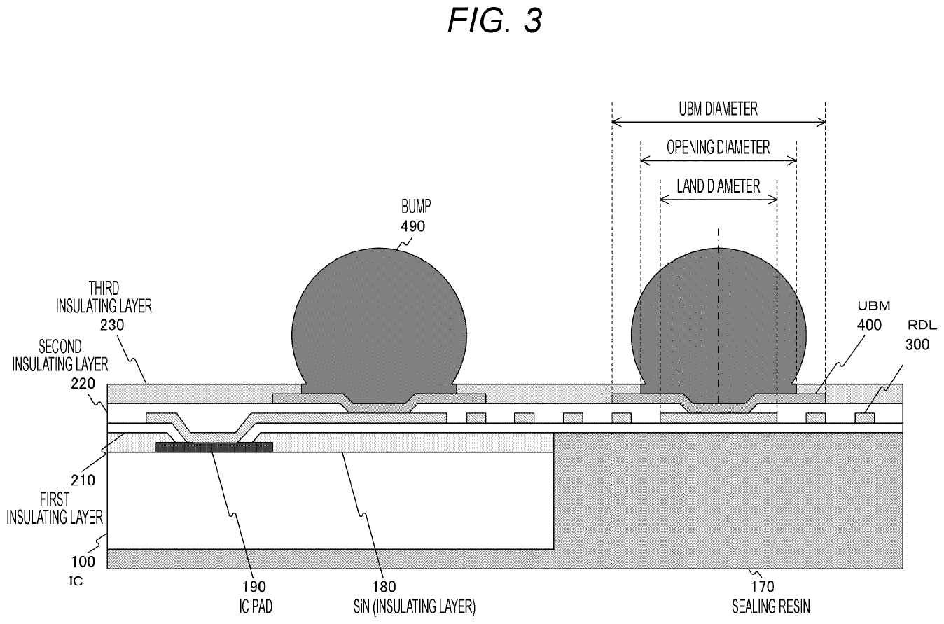

FIG. 3 is a cross-sectional view illustrating a second example of the semiconductor package according to the first embodiment of the present technology.

The second example of the semiconductor package assumes a fan out wafer level package (FOWLP). The FOWLP has a structure in which the terminal is expanded to the outside of the chip as compared with the above-described WLCSP.

This semiconductor package has a structure in which the IC 100 is sealed with a sealing resin 170. Then, the structure is similar to that of the above-described first example except that the position of the bump 490 is disposed outside the IC 100. That is, the diameter of the under bump metal layer 400 is formed to be larger than the opening diameter of the outermost layer. As a result, the under bump metal layer 400 inhibits or reduces transmission of a force to the land 310 or the RDL 300 via the bump 490, so that the drop test characteristics and impact resistance can be improved.

In addition, similarly to the above-described first example, the diameter of the under bump metal layer 400 is formed to be larger than the diameter of the land 310 in the RDL 300 connected to the under bump metal layer 400. As a result, the wiring density between the bumps 490 can be improved.

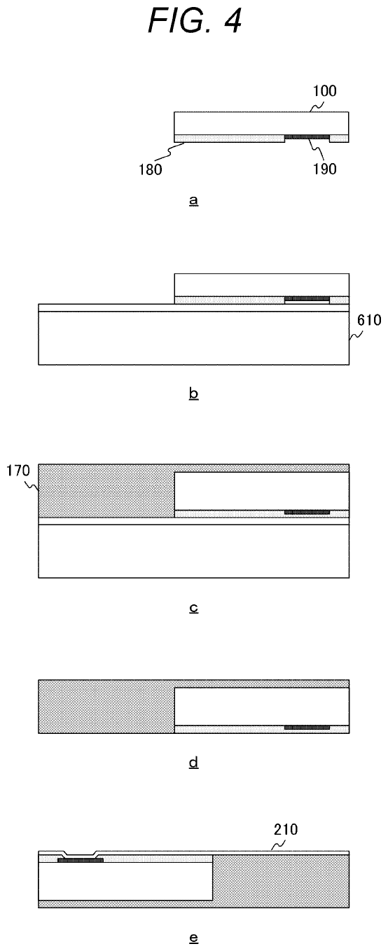

FIG. 4 is a first view illustrating a manufacturing process example of the second example of the semiconductor package according to the first embodiment of the present technology. First, the IC 100 in a of the drawing is attached to a support material 610 in a face-down state as illustrated in b of the drawing.

Then, as illustrated in c of the drawing, resin sealing is performed with the sealing resin 170. Here, as a material of the sealing resin 170, an epoxy resin, a phenol resin, or the like can be considered.

Then, as illustrated in d of the drawing, the support material 610 is peeled off.

Next, as illustrated in e of the drawing, the first insulating layer 210 is formed on the surface in the face-up state by an exposure development technique.

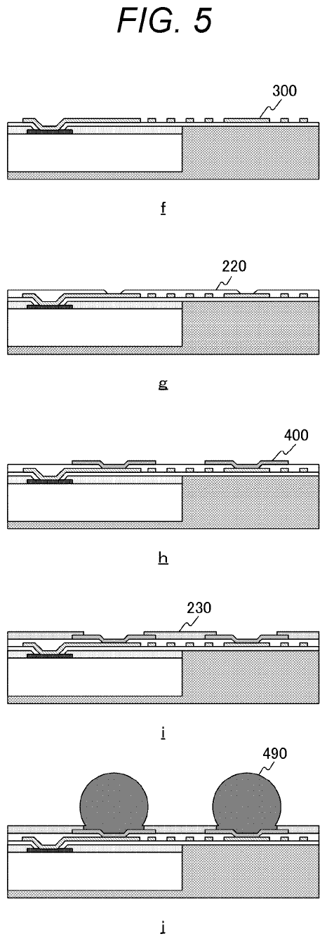

FIG. 5 is a second view illustrating a manufacturing process example of the second example of the semiconductor package according to the first embodiment of the present technology.

Next, as illustrated in f of the drawing, the RDL 300 is formed on the first insulating layer 210 by a plating process. Then, as illustrated in g of the drawing, the second insulating layer 220 is formed by an exposure development technique.

Next, as illustrated in h of the drawing, the under bump metal layer 400 is formed. As a material of the under bump metal layer 400, for example, a Cu under bump metal layer using Ni as a barrier metal in a TiW seed layer is conceivable.

Next, as illustrated in i of the drawing, the third insulating layer 230 is formed to have an SMD structure.

Finally, as illustrated in j of the drawing, the bump 490 serving as an external terminal is attached.

### Third Example

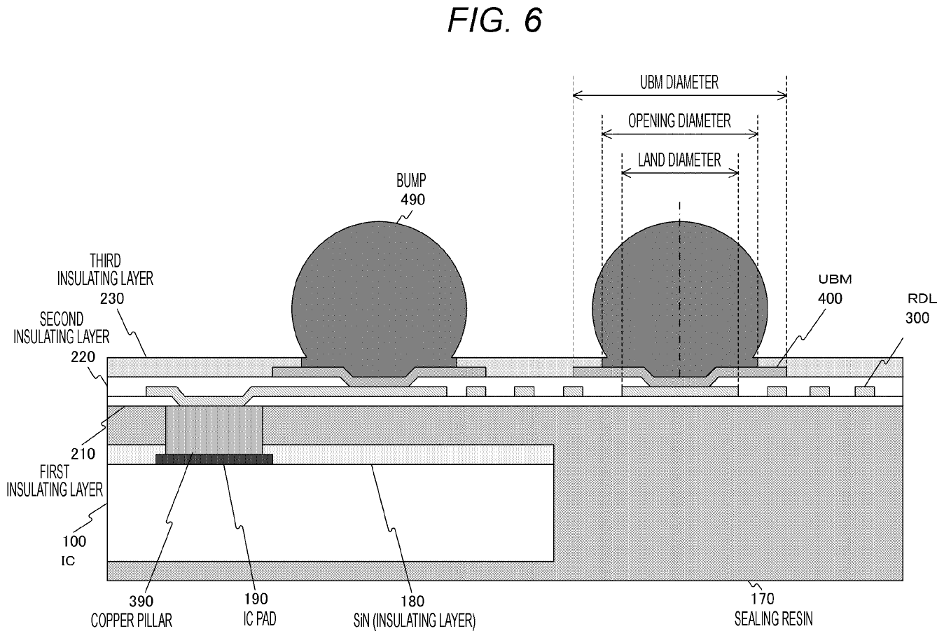

FIG. 6 is a cross-sectional view illustrating a third example of the semiconductor package according to the first embodiment of the present technology.

The third example of the semiconductor package has a structure in which a copper pillar 390 is further provided in the FOWLP structure. Other structures are similar to those of the second example described above. That is, the diameter of the under bump metal layer 400 is formed to be larger than the opening diameter of the outermost layer. As a result, the under bump metal layer 400 inhibits or reduces transmission of a force to the land 310 or the RDL 300 via the bump 490, so that the drop test characteristics and impact resistance can be improved.

Further, similarly to the above-described second example, the diameter of the under bump metal layer 400 is formed to be larger than the diameter of the land 310 in the RDL 300 connected to the under bump metal layer 400. As a result, the wiring density between the bumps 490 can be improved.

### Fourth Example

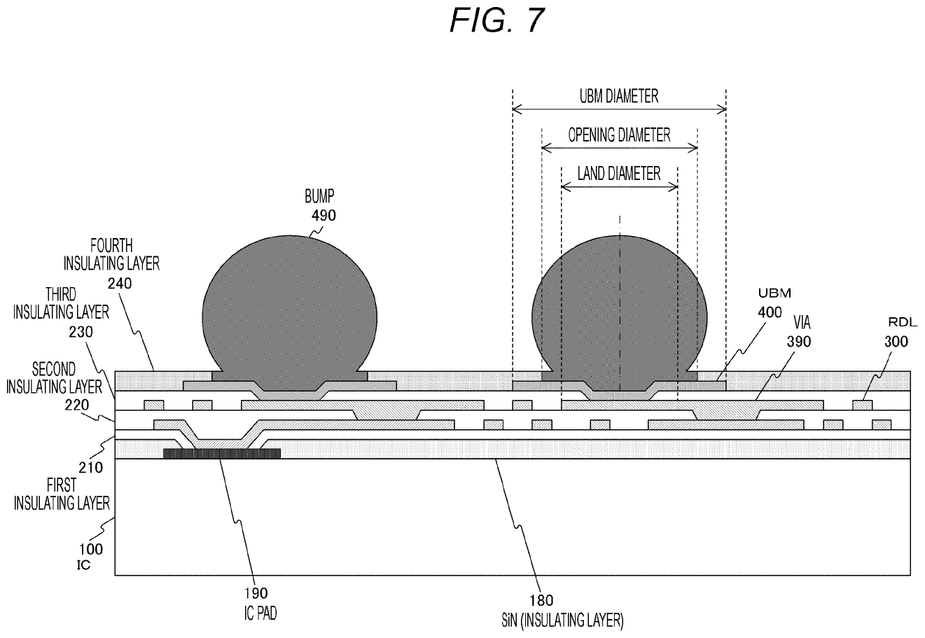

FIG. 7 is a cross-sectional view illustrating a fourth example of the semiconductor package according to the first embodiment of the present technology.

The fourth example of the semiconductor package has a structure in which two layers of the RDL 300 are provided in the WLCSP structure. Other structures are similar to those of the first example described above. That is, the diameter of the under bump metal layer 400 is formed to be larger than the opening diameter of the outermost layer. As a result, the under bump metal layer 400 inhibits or reduces transmission of a force to the land 310 or the RDL 300 via the bump 490, so that the drop test characteristics and impact resistance can be improved.

In addition, similarly to the above-described first example, the diameter of the under bump metal layer 400 is formed to be larger than the diameter of the land 310 in the RDL 300 connected to the under bump metal layer 400. As a result, the wiring density between the bumps 490 can be improved.

Note that, in the fourth example, a structure in which two layers of the RDL 300 are provided is assumed, but three or more layers of the RDL 300 may be provided.

### Fifth Example

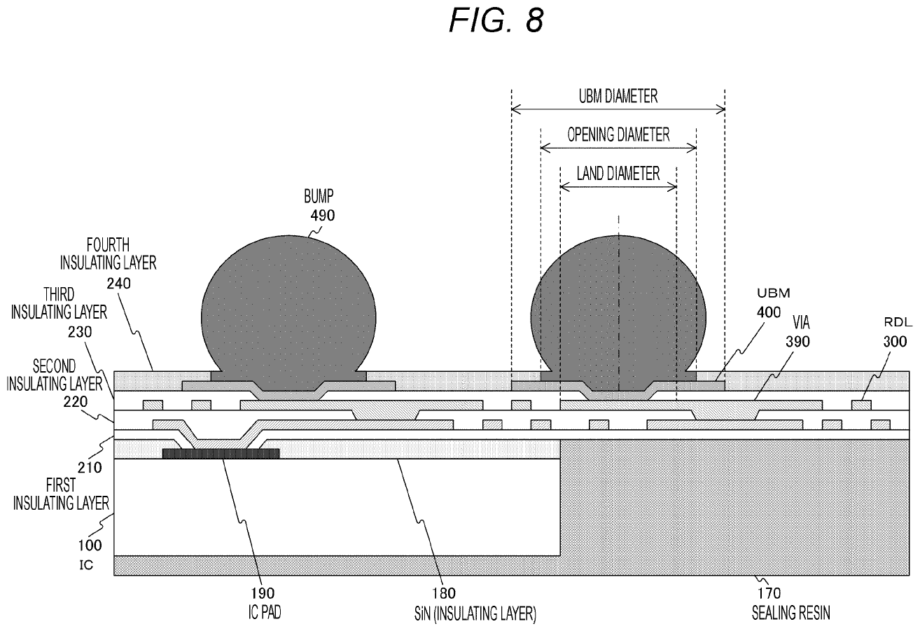

FIG. 8 is a cross-sectional view illustrating a fifth example of the semiconductor package according to the first embodiment of the present technology.

The fifth example of the semiconductor package has a structure in which two layers of the RDL 300 are provided in the FOWLP structure. Other structures are similar to those of the second example described above. That is, the diameter of the under bump metal layer 400 is formed to be larger than the opening diameter of the outermost layer. As a result, the under bump metal layer 400 inhibits or reduces transmission of a force to the land 310 or the RDL 300 via the bump 490, so that the drop test characteristics and impact resistance can be improved.

Further, similarly to the above-described second example, the diameter of the under bump metal layer 400 is formed to be larger than the diameter of the land 310 in the RDL 300 connected to the under bump metal layer 400. As a result, the wiring density between the bumps 490 can be improved.

Note that, in the fifth example, a structure in which two layers of the RDL 300 are provided is assumed, but three or more layers of the RDL 300 may be provided.

### Sixth Example

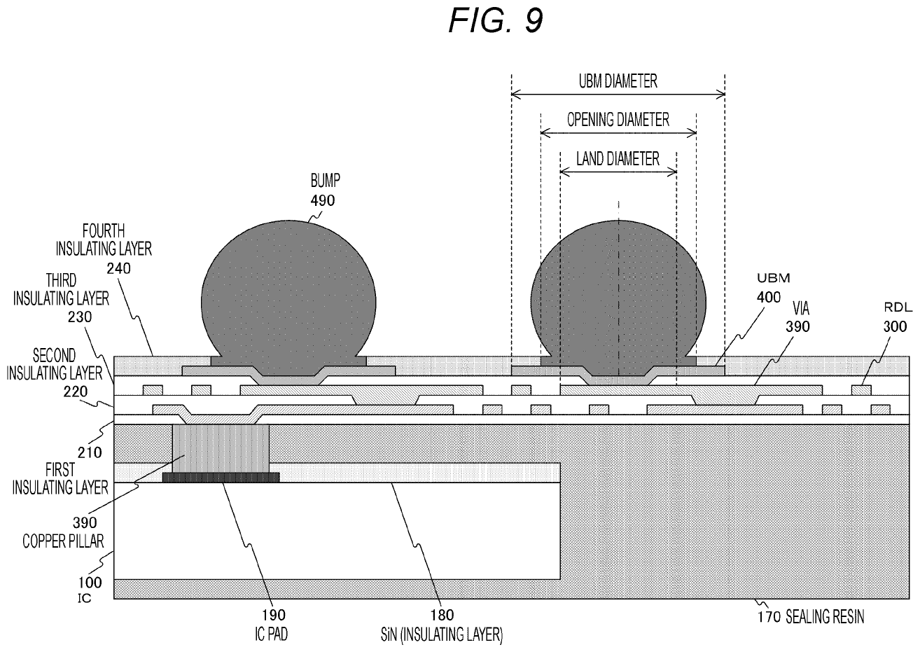

FIG. 9 is a cross-sectional view illustrating a sixth example of the semiconductor package according to the first embodiment of the present technology.

The sixth example of the semiconductor package has a structure in which two layers of RDL 300 are provided and the copper pillar 390 is further provided in the FOWLP structure. Other structures are similar to those of the fifth example described above. That is, the diameter of the under bump metal layer 400 is formed to be larger than the opening diameter of the outermost layer. As a result, the under bump metal layer 400 inhibits or reduces transmission of a force to the land 310 or the RDL 300 via the bump 490, so that the drop test characteristics and impact resistance can be improved.

Further, similarly to the above-described fifth example, the diameter of the under bump metal layer 400 is formed to be larger than the diameter of the land 310 in the RDL 300 connected to the under bump metal layer 400. As a result, the wiring density between the bumps 490 can be improved.

Note that, in the sixth example, a structure in which two layers of the RDL 300 are provided is assumed, but three or more layers of the RDL 300 may be provided.

As described above, in the first embodiment of the present technology, the diameter of the under bump metal layer 400 is formed to be larger than the opening diameter of the outermost layer. As a result, transmission of force to the land 310 and the RDL 300 can be inhibited or reduced, and the drop test characteristics and impact resistance can be improved.

### 2. Second Embodiment

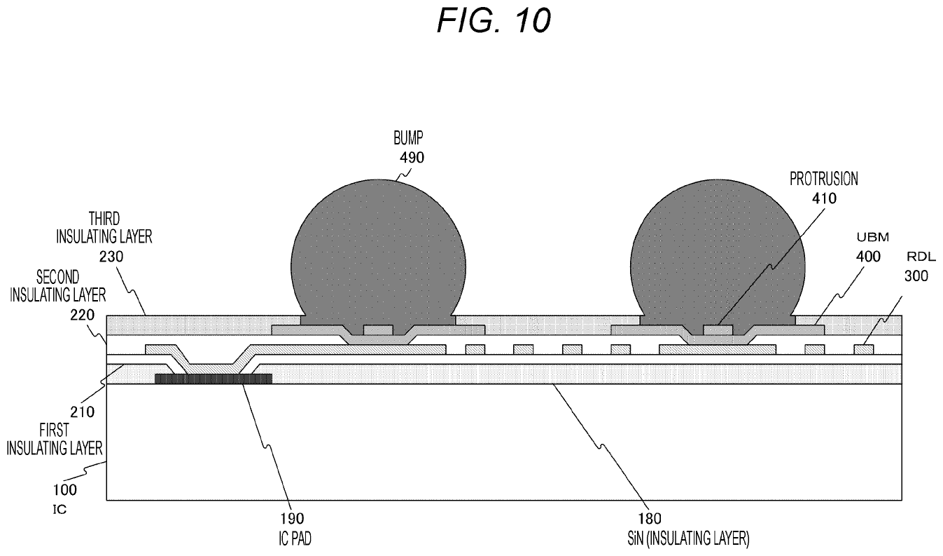

FIG. 10 is a cross-sectional view illustrating a structural example of a semiconductor package according to a second embodiment of the present technology.

In the semiconductor package according to the second embodiment, the under bump metal layer 400 includes a protrusion 410 at an interface with the bump 490. As a result, the connection of the bumps 490 can be strengthened. The protrusion 410 is formed by the same metal (for example, copper) plating as the RDL 300, and nickel (Ni) or nickel gold (Ni/Au) plating is added as necessary.

However, also in the second embodiment, similarly to the first embodiment described above, the diameter of the under bump metal layer 400 is formed to be larger than the opening diameter of the outermost layer. In addition, the diameter of the under bump metal layer 400 is formed to be larger than the diameter of the land 310 in the RDL 300 connected to the under bump metal layer 400.

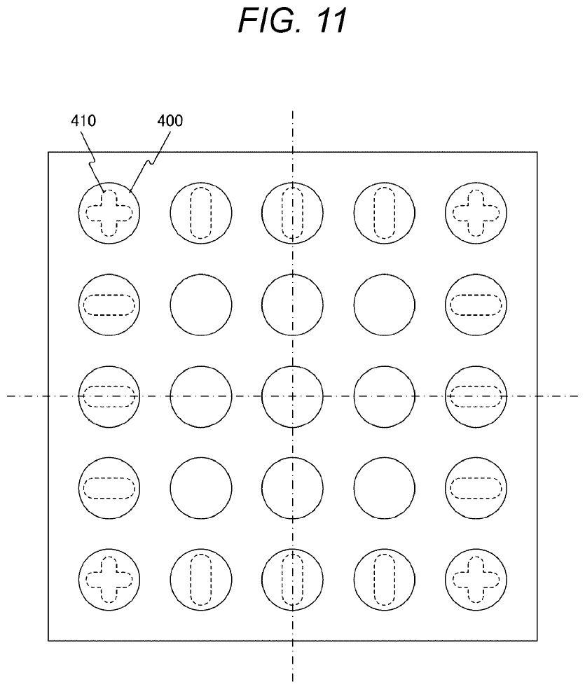

FIG. 11 is a plan view illustrating an arrangement example of the protrusions 410 according to the second embodiment of the present technology.

As illustrated in the drawing, it is desirable to arrange protrusions 410 having cross-shaped or L-shaped planar shapes with large protrusion areas for the corner terminals arranged in the outer peripheral portion of the chip. This makes it possible to further strengthen the connection of the bumps in the outer peripheral portion of the chip.

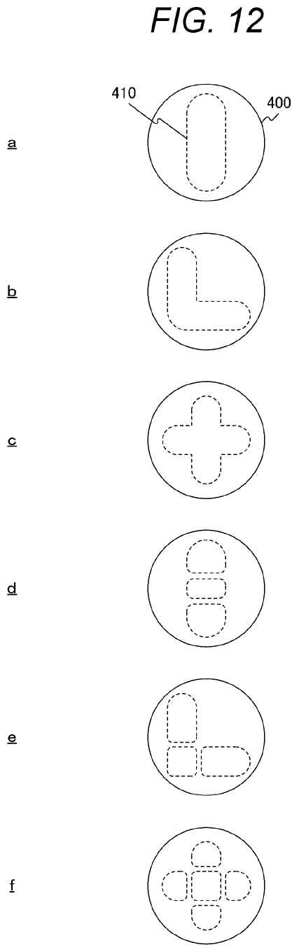

FIG. 12 is a plan view illustrating a planar shape example of the protrusion 410 according to the second embodiment of the present technology.

In the drawing, a is an example of the shape of the oval protrusion 410. In the drawing, b is an example of the shape of the L-shaped protrusion 410. In the drawing, c is an example of the shape of the cross-shaped protrusion 410.

In the drawing, d is an example of the shape of the protrusion 410 obtained by dividing the oval shape into a plurality of parts. In the drawing, e is a shape example of the protrusion 410 obtained by dividing the L shape into a plurality of parts. In the drawing, f is an example of the shape of the protrusion 410 obtained by dividing the cross shape into a plurality of parts. In this manner, by forming the protrusions into a plurality of divided shapes, the protrusion area can be further increased, and the connection of the bumps can be strengthened.

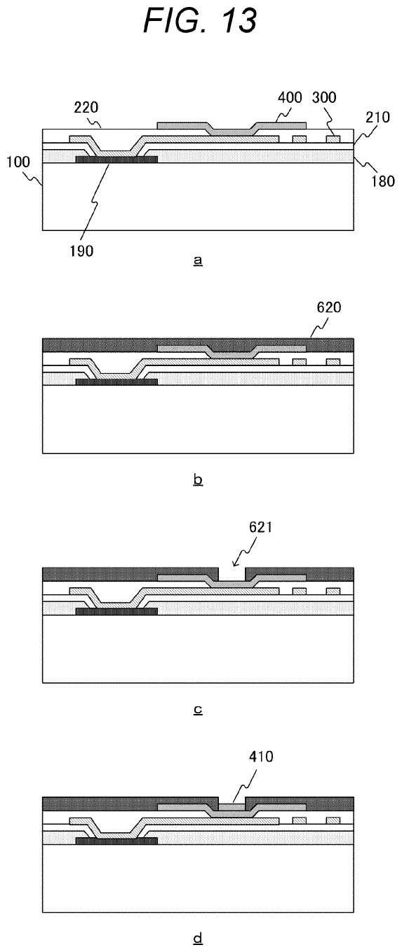

FIG. 13 is a first view illustrating a manufacturing process example of the protrusion 410 according to the second embodiment of the present technology.

As illustrated in a of the drawing, after the under bump metal layer 400 is formed on the second insulating layer 220, a resist 620 for forming the protrusion 410 is applied as illustrated in b of the drawing. Then, as illustrated in c of the drawing, an unnecessary portion 621 is deleted by exposure and development.

Next, as illustrated in d of the drawing, the protrusion 410 is formed by copper plating. Further, nickel (Ni) or nickel gold (Ni/Au) plating may be further added as necessary.

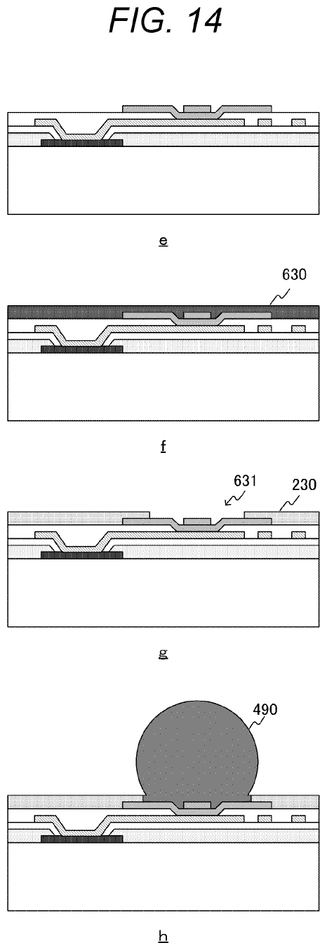

FIG. 14 is a second view illustrating a manufacturing process example of the protrusion 410 according to the second embodiment of the present technology.

As illustrated in e of the drawing, the resist 620 for forming the protrusion 410 is removed. Then, as illustrated in f of the drawing, a resist 630 for forming the third insulating layer 230 is applied. Thereafter, as illustrated in g of the drawing, an unnecessary portion 631 is deleted by exposure and development.

Then, as illustrated in h of the drawing, after mounting the solder ball, the bump 490 is formed by reflow.

As described above, according to the second embodiment of the present technology, since the under bump metal layer 400 includes the protrusion 410 at the interface with the bump 490, the connection between the under bump metal layer 400 and the bump 490 can be strengthened.

### Modification

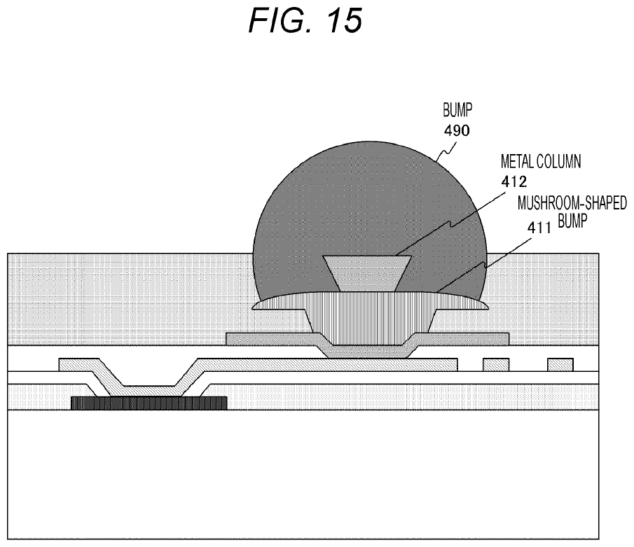

FIG. 15 is a cross-sectional view illustrating a modification of the protrusion shape according to the second embodiment of the present technology.

The modification of the protrusion shape in the second embodiment has a structure in which a metal column 412 having a reverse taper is formed on a mushroom-shaped bump 411 and covered with a solder ball to generate a bump 490. As described above, by forming the reverse tapered metal column 412 in the bump 490, there is an effect of strengthening the connection with the bump 490.

### 3. Third Embodiment

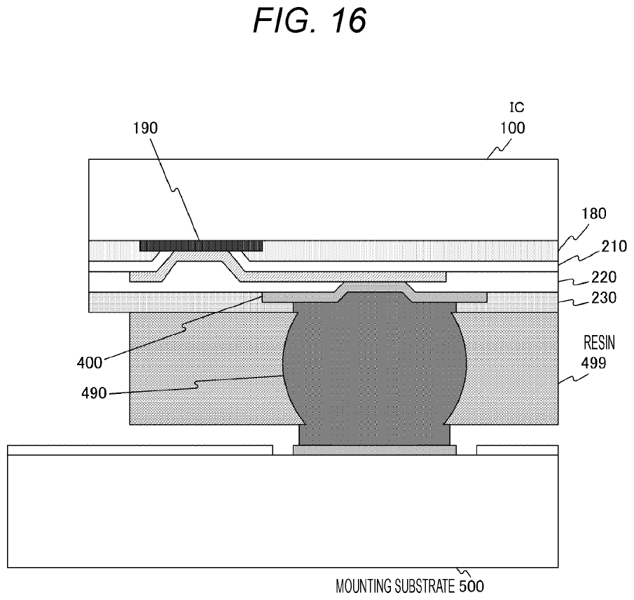

FIG. 16 is a cross-sectional view illustrating a structural example of a semiconductor package according to a third embodiment of the present technology.

The semiconductor package according to the third embodiment has a structure in which the base portion of the bump 490 is reinforced by being covered with a resin 499. This drawing illustrates a state in which the chip is mounted on a mounting substrate 500 by face-down. Reinforcement with the resin 499 can reinforce connection of the bumps 490.

However, also in the third embodiment, similarly to the first embodiment described above, the diameter of the under bump metal layer 400 is formed to be larger than the opening diameter of the outermost layer. In addition, the diameter of the under bump metal layer 400 is formed to be larger than the diameter of the land 310 in the RDL 300 connected to the under bump metal layer 400.

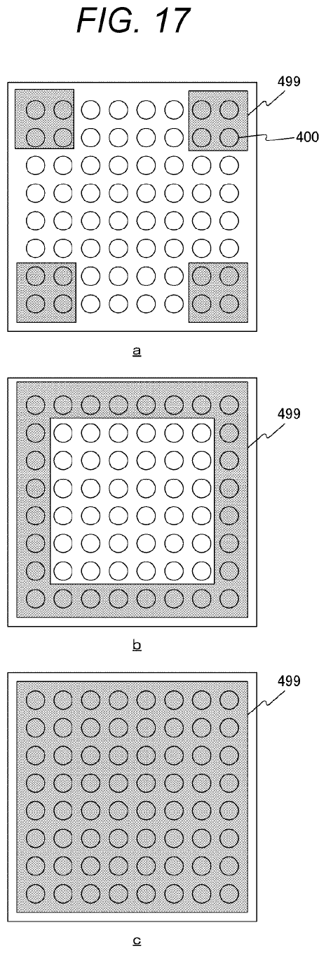

FIG. 17 is a plan view illustrating an arrangement example of the resin 499 according to the third embodiment of the present technology.

As illustrated in a of the drawing, it is conceivable that the region to be reinforced by the resin 499 is provided at the corner portions of the four corners of the semiconductor package where the distortion concentrates. Further, as illustrated in b of the drawing, it may be provided on the outer peripheral portion of the semiconductor package. In addition, as illustrated in c of the drawing, the entire semiconductor package may be covered with the resin 499 as necessary. However, as the region covered by the resin 499 becomes larger, package warpage is more likely to occur due to a difference in linear expansion coefficient between silicon of the semiconductor package and the resin 499, and thus it is necessary to appropriately select which type to use in accordance with the package size.

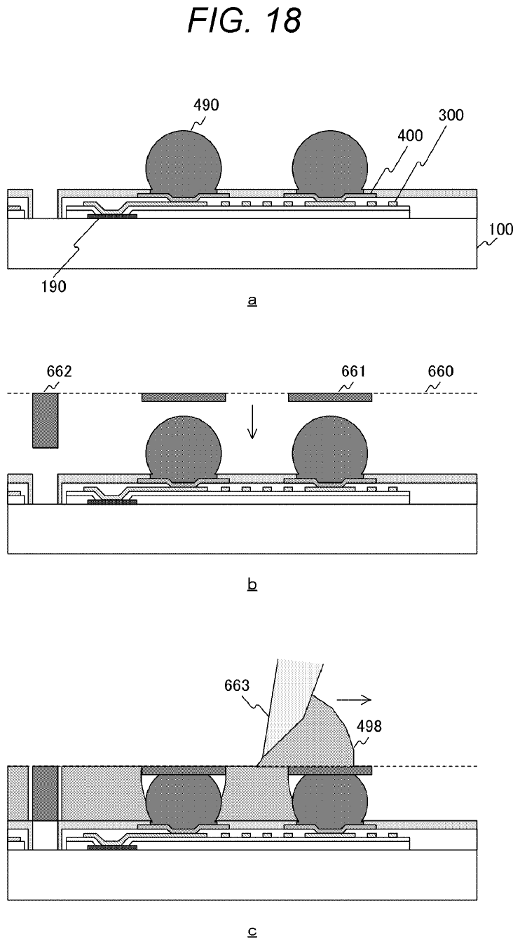

FIG. 18 is a first view illustrating a first example of the process of forming the resin 499 according to the third embodiment of the present technology. In a first example of the process of forming the resin 499, resin sealing is performed by screen printing.

First, as illustrated in a of the drawing, a wafer on which the bumps 490 are mounted is prepared. Then, as illustrated in b of the drawing, the resin print screen 660 is set on the surface side on which the bump 490 is mounted. The resin print screen 660 includes a bump mask 661 for masking the bumps 490 and a dicing area mask 662 for masking the dicing area.

Then, as illustrated in c of the drawing, a liquid resin 498 is screen-printed by a squeegee 663.

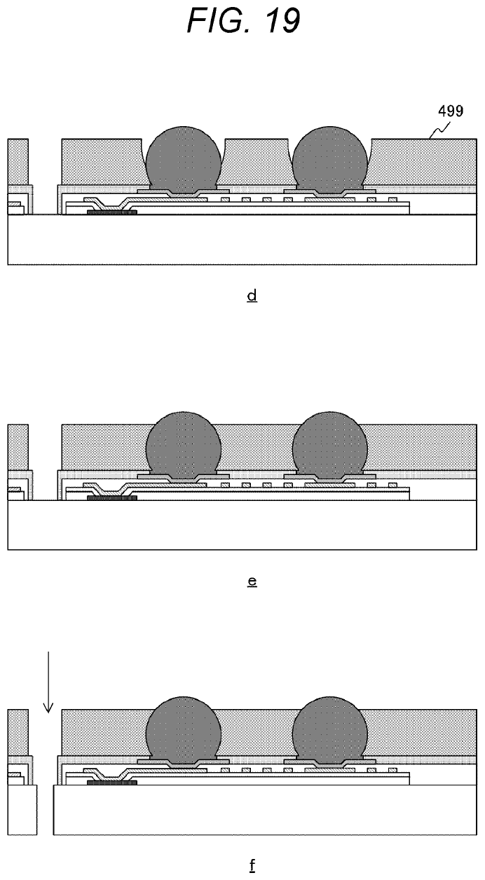

FIG. 19 is a second view illustrating the first example of the process of forming the resin 499 according to the third embodiment of the present technology.

Thereafter, as illustrated in d of the drawing, the resin print screen 660 is removed. In this state, as illustrated in e of the drawing, the liquid resin 498 is heated and cured. As a result, the liquid resin 498 is cured and shrunk to be lower than the height of the bump 490.

Thereafter, as illustrated in f of the drawing, dicing is performed in a dicing area and cut into individual pieces.

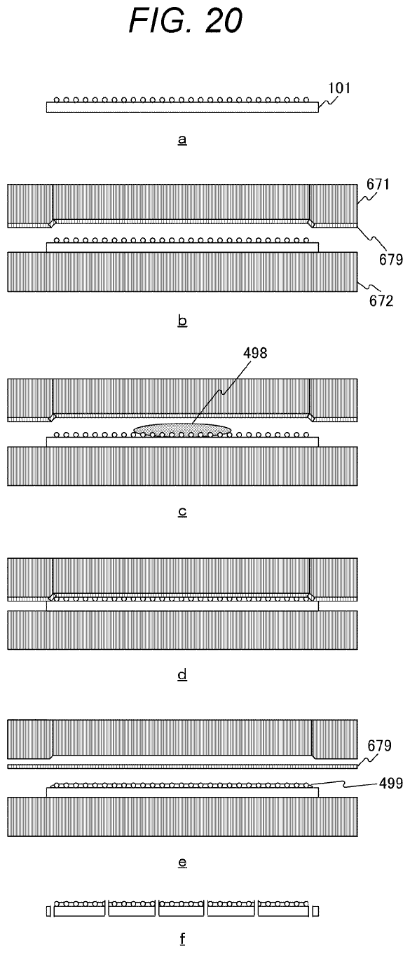

FIG. 20 is a first view illustrating a second example of the process of forming the resin 499 according to the third embodiment of the present technology. In the second example of the process of forming the resin 499, resin sealing is performed using a mold die.

First, as illustrated in a of the drawing, a wafer 101 on which the bump 490 is mounted is prepared. Then, as illustrated in b of the drawing, the wafer 101 is set in the mold dies 671 and 672. An elastic release film 679 is attached to the upper mold die 671.

Thereafter, as illustrated in c of the drawing, the liquid resin 498 or the granular resin is supplied to the surface side of the wafer 101 on which the bumps 490 are mounted. Then, as illustrated in d of the drawing, the film is pressurized and heated and cured.

Thereafter, as illustrated in e of the drawing, the release film 679 is peeled off and the wafer 101 is taken out. Then, as illustrated in f of the drawing, dicing is performed to cut into individual pieces.

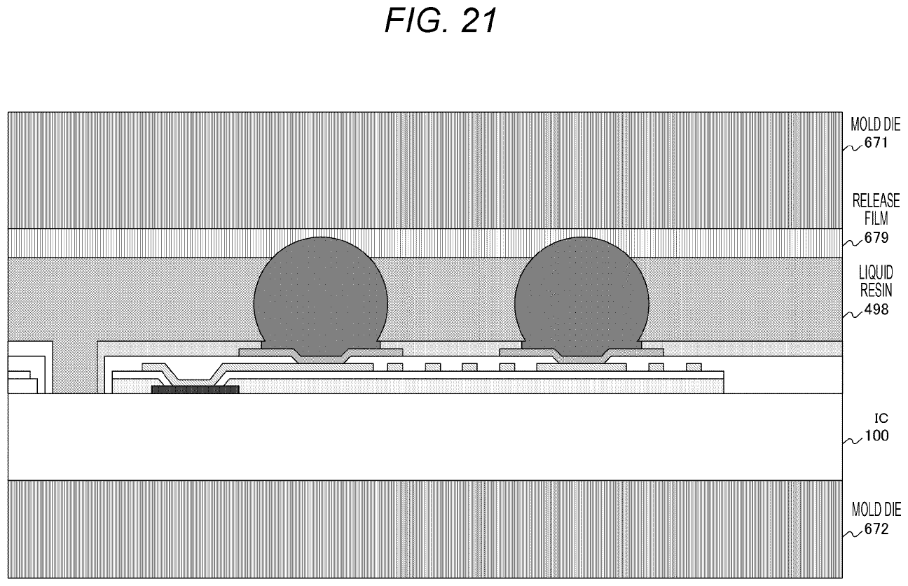

FIG. 21 is a second view illustrating the second example of the process of forming the resin 499 according to the third embodiment of the present technology.

The drawing illustrates a state in which the liquid resin 498 is supplied, and pressurized and heated and cured. By pressurizing from above through the release film 679, the bump 490 is pointed out. As a result, a part of the bump 490 is exposed from the resin 499 after the release film 679 is peeled off.

As described above, according to the third embodiment of the present technology, by covering the base portion of the bump 490 with the resin 499, the connection of the bump 490 can be strengthened, and distortion concentrated on the bump base portion of the package corner can be reduced. In addition, since it is not necessary to use the underfill, the repair is facilitated, and the component mounting prohibition area around the package can be eliminated.

### 4. Fourth Embodiment

### First Example

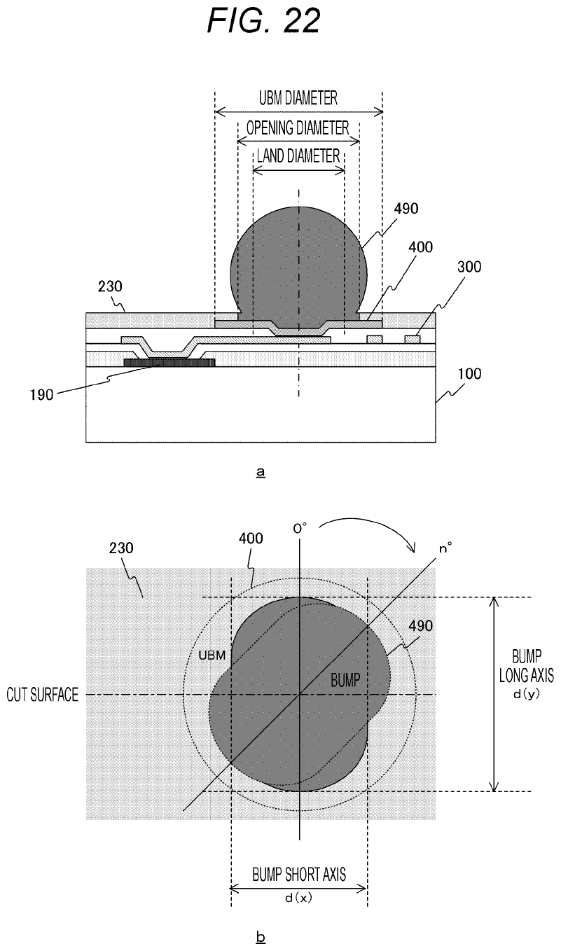

FIG. 22 is a cross-sectional view illustrating a first example of a structure of a semiconductor package according to a fourth embodiment of the present technology.

In the semiconductor package according to the fourth embodiment, at least a part of the bump 490 has an oval coin planar shape. As a result, the stress acting on the bump 490 can be reduced.

The bump 490 has an oval coin shape having a short axis d (x) and a long axis d (y). The opening shape of the third insulating layer 230 and the shape of the bump 490 are the same oval coin. Also in the first example of the fourth embodiment, similarly to the above-described first embodiment, the diameter of the under bump metal layer 400 is formed to be larger than any of the opening diameters of the outermost layers. In addition, the diameter of the under bump metal layer 400 is formed to be larger than any of the diameters of the lands 310 in the RDL 300 connected to the under bump metal layer 400.

Further, as described below, the bump 490 can be adjusted to a state of being rotated rightward by a predetermined angle (n°) from each central axis.

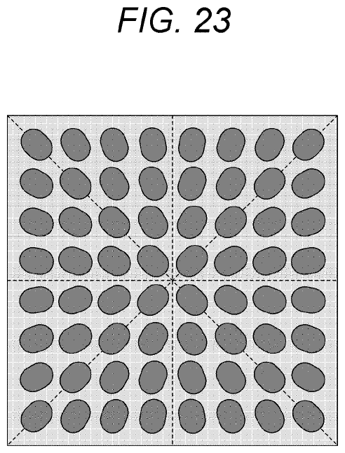

FIG. 23 is a plan view illustrating a first arrangement example of the bumps 490 according to the fourth embodiment of the present technology.

In the first arrangement example, each of the bumps 490 has an oval coin shape, and has a layout in which all extend radially from the center of the chip or package.

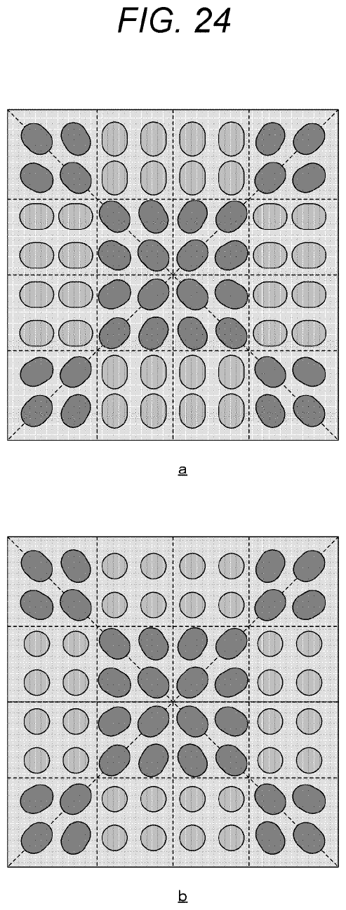

FIG. 24 is a plan view illustrating a second arrangement example of the bumps 490 according to the fourth embodiment of the present technology.

In the second arrangement example, each of the bumps 490 has a layout that spreads radially from the center of the chip or the package in the region across the diagonal of the chip or the package. The bump 490 in the other region may have an oval coin shape rotated in the vertical direction or the horizontal direction as illustrated in a of the drawing, or may have a circular shape as illustrated in b of the drawing.

For example, in the case of the FOWLP, the IC chip exists in the region of the central portion, but the stress acting on the IC chip can be reduced by the layout of making the bumps 490 in the region of the central portion radially spread.

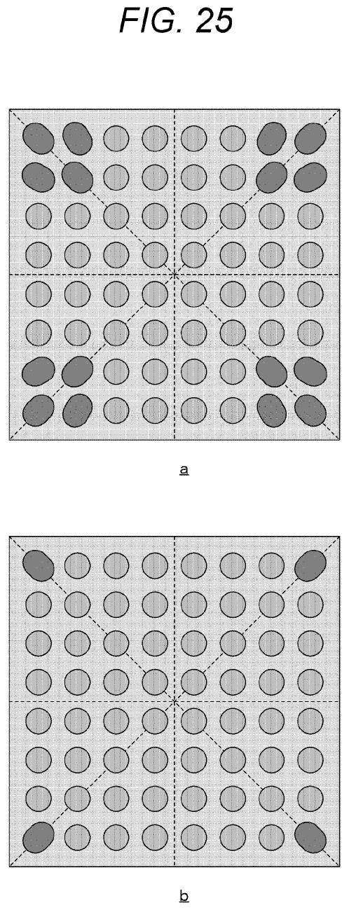

FIG. 25 is a plan view illustrating a third arrangement example of the bumps 490 according to the fourth embodiment of the present technology.

In the third arrangement example, the oval coin-shaped bump and the circular bump are mixed, and the bump in the corner region of the chip or the package most affected by the stress has the oval shape, and the layout is such that the bumps radially spread from the center of the chip or the package.

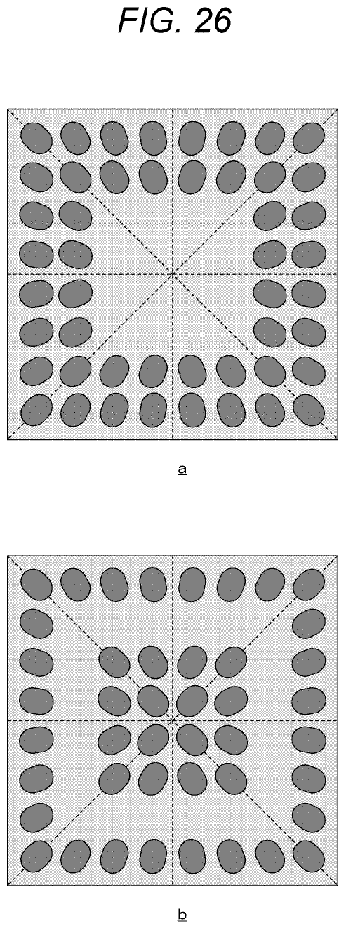

FIG. 26 is a plan view illustrating a fourth arrangement example of the bumps 490 according to the fourth embodiment of the present technology.

In the fourth arrangement example, the bumps 490 are arranged only on the outer peripheral portion of the chip or the package as illustrated in a of the drawing, or only on the outer peripheral portion and the central portion as illustrated in b of the drawing. Each of the bumps 490 has an oval coin shape, and has a layout in which all extend radially from the center of the chip or package.

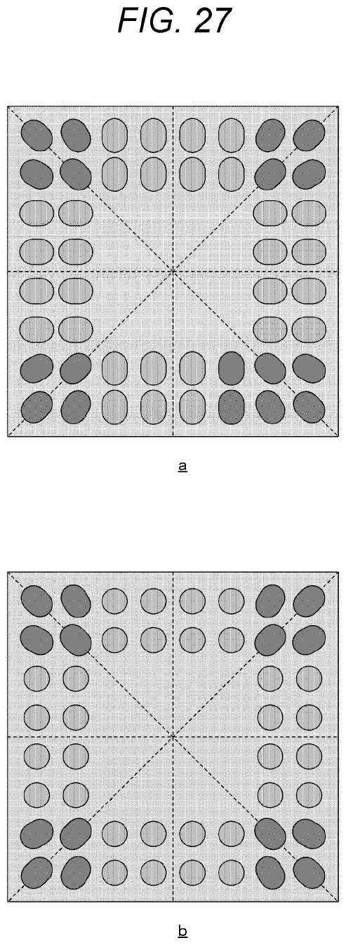

FIG. 27 is a plan view illustrating a fifth arrangement example of the bumps 490 according to the fourth embodiment of the present technology.

In the fifth arrangement example, the bumps 490 have a layout that spreads radially from the center of the chip or package at the four corner portions. In addition, in any case, the bump 490 is not disposed in a portion other than the outer peripheral portion. In addition, the bumps 490 at the outer peripheral portions other than the corner portions at the four corners may have an oval coin shape rotated in the vertical direction or the horizontal direction as illustrated in a of the drawing or may have a circular shape as illustrated in b of the drawing.

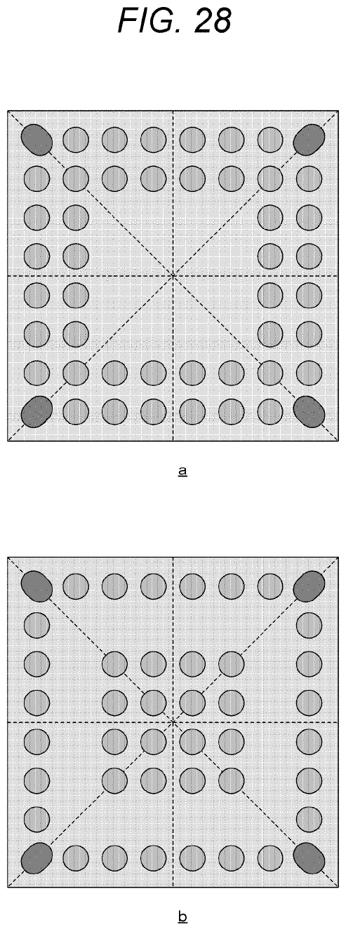

FIG. 28 is a plan view illustrating a sixth arrangement example of the bumps 490 according to the fourth embodiment of the present technology.

In the sixth arrangement example, only the bumps 490 at the four corners have an oval coin shape radially expanding from the center of the chip or the package. A circular bump may be arranged at the outer peripheral portion as illustrated in a of the drawing, or a circular bump may be further arranged at the central portion as illustrated in b of the drawing.

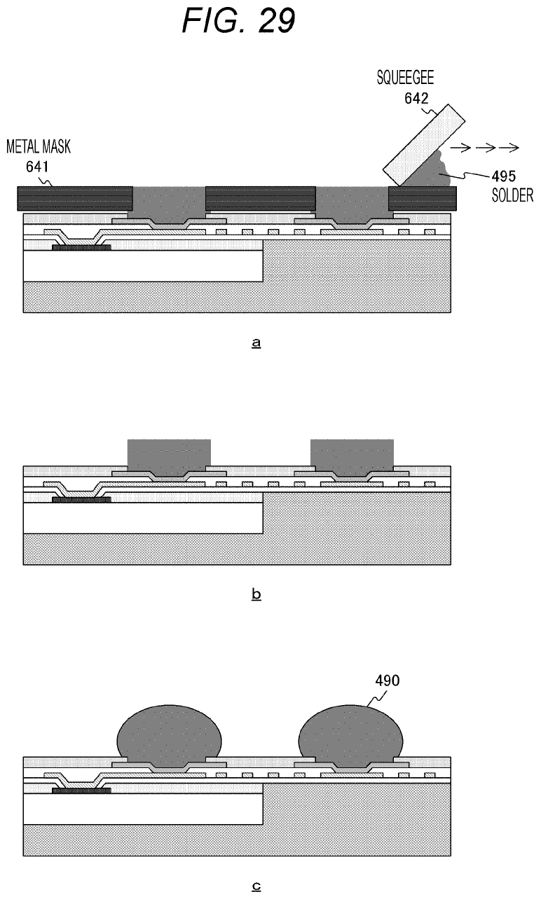

FIG. 29 is a first view illustrating an example of the process of forming the bump 490 of the first example according to the fourth embodiment of the present technology.

When the bump 490 is formed, as illustrated in a of the drawing, solder printing is performed by filling the paste-like solder 495 with a squeegee 642 using a metal mask 641 having an oval coin-shaped opening. After the solder printing, the metal mask 641 is removed.

Thereafter, reflow is performed as illustrated in b of the drawing, and the bump 490 is formed as illustrated in c of the drawing.

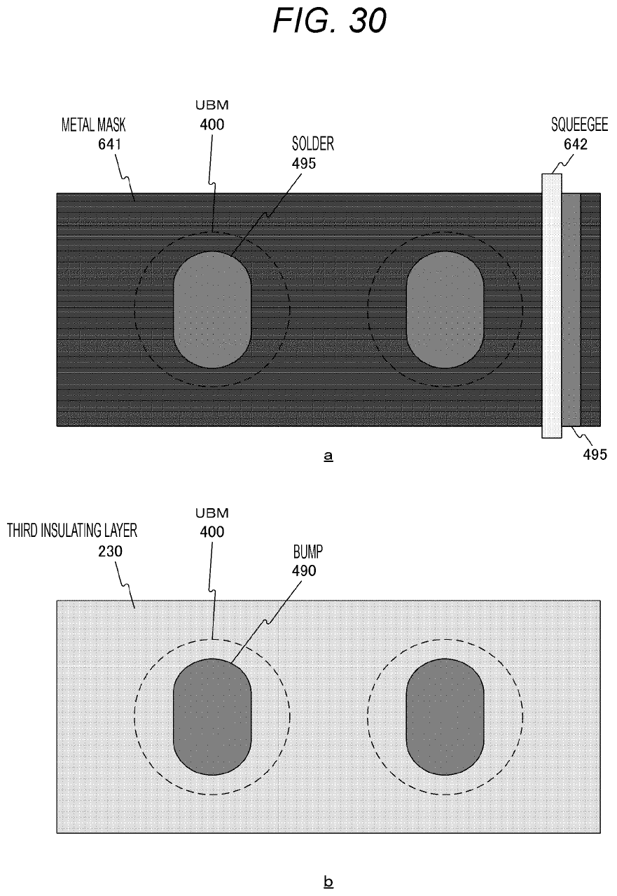

FIG. 30 is a second view illustrating an example of the process of forming the bump 490 of the first example according to the fourth embodiment of the present technology.

a of the drawing illustrates a state in which the paste-like solder 495 is filled with the squeegee 642 using the metal mask 641 having an oval coin-shaped opening. In addition, b of the drawing illustrates a state in which the oval coin-shaped bump 490 is formed after reflow.

### Second Example

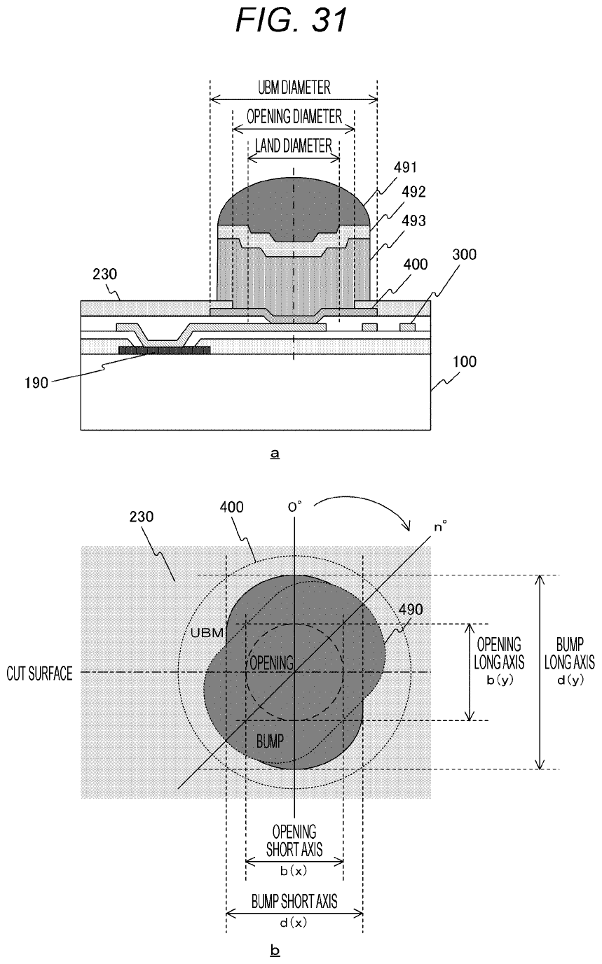

FIG. 31 is a cross-sectional view illustrating a second example of the structure of the semiconductor package according to the fourth embodiment of the present technology.

In the second example of the fourth embodiment, a copper pillar bump 493 is formed on the under bump metal layer 400, and solder 491 is formed thereon via nickel 492. Similarly to the above-described first example, the copper pillar bump 493 has an oval coin shape having a short axis d (x) and a long axis d (y). The opening shape of the third insulating layer 230 may be the same oval coin shape as the copper pillar bump 493 or may be a circular shape different from the copper pillar bump 493.

Also in the second example of the fourth embodiment, similarly to the above-described first embodiment, the diameter of the under bump metal layer 400 is formed to be larger than the opening diameter of the outermost layer. In addition, the diameter of the under bump metal layer 400 is formed to be larger than the diameter of the land 310 in the RDL 300 connected to the under bump metal layer 400. In addition, similarly to the above-described first example, the copper pillar bump 493 can be adjusted to a state of being rotated to the right by a predetermined angle (n°) from each central axis.

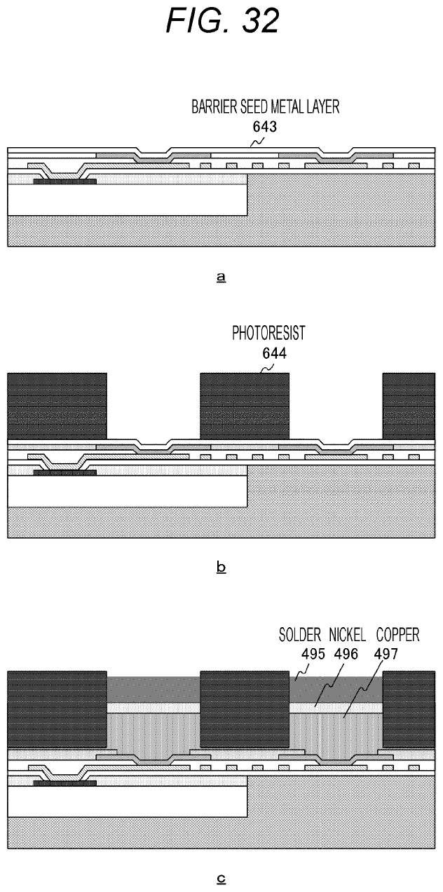

FIG. 32 is a first view illustrating an example of the process of forming the copper pillar bump 493 of the second example according to the fourth embodiment of the present technology.

As illustrated in a of the drawing, the third insulating layer 230 is formed after the formation of the under bump metal layer 400. The opening shape of the third insulating layer 230 may be an oval coin shape or circular shape. In a case where the opening shape of the third insulating layer 230 is an oval coin shape, the direction of the opening is the same as that of the copper pillar bump 493 to be formed later. Then, as illustrated in a of the drawing, a barrier seed metal layer 643 is formed by a plasma vapor deposition (PVD) process.

Next, as illustrated in b of the drawing, a photoresist 644 is applied. Then, a pattern is formed on the photoresist 644 by a lithography process. The opening shape of the photoresist 644 is an oval coin shape having a short axis and a long axis. The direction of the opening can be arbitrarily adjusted.

Thereafter, as illustrated in c of the drawing, copper 497 is plated and formed by an electrolytic plating process. Then, nickel 496 and solder 495 are plated and formed by an electroless plating process.

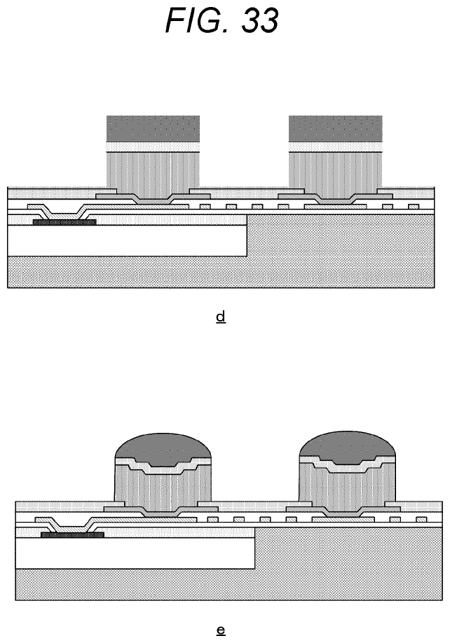

FIG. 33 is a second view illustrating an example of the process of forming the copper pillar bump 493 of the second example according to the fourth embodiment of the present technology.

Then, as illustrated in d of the drawing, after the photoresist 644 is removed, the barrier seed metal layer 643 is removed by an etching process. Thereafter, as illustrated in e of the drawing, the copper pillar bump 493 of an oval coin shape is formed by performing reflow.

As described above, according to the fourth embodiment of the present technology, it is possible to relax the stress of the chip by making the bump shape oval coin-shape and radially spreading the direction. In addition, warpage of the chip due to thermal shrinkage can be prevented by adjusting the layout of the oval coin-shaped bump.

### 5. Fifth Embodiment

### First Example

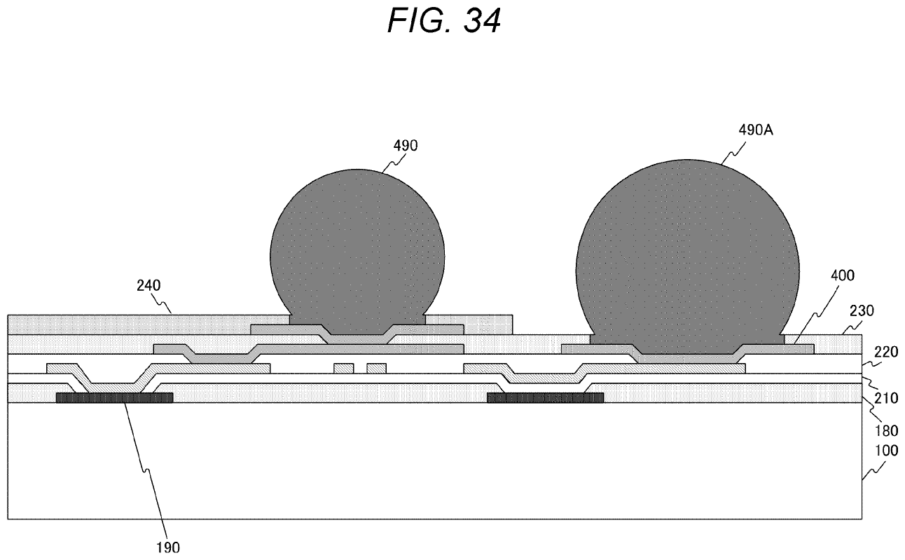

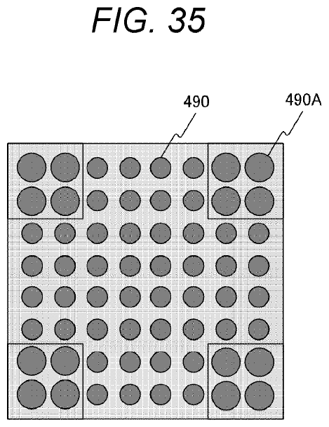

FIG. 34 is a cross-sectional view illustrating a first example of a structure of a semiconductor package according to a fifth embodiment of the present technology. FIG. 35 is a plan view illustrating the first example of the structure of the semiconductor package according to the fifth embodiment of the present technology.

The first example of the fifth embodiment has a structure in which the size of bumps 490A at the corner portions of the four corners to which a larger stress is applied is increased and the height thereof is increased. As a result, the stress at the corner portions can be absorbed, and the stress resistance can be improved. However, in order to adjust the height of each bump finally formed, the bump 490A having an increased size has a structure in which the number of layers of the RDL 300 is reduced.

That is, the under bump metal layer 400 of the bumps 490A at the corner portions is formed between the second insulating layer 220 and the third insulating layer 230, and the under bump metal layer 400 of the other bumps 490 is formed between the third insulating layer 230 and the fourth insulating layer 240.

Also in the first example of the fifth embodiment, similarly to the above-described first embodiment, the diameter of the under bump metal layer 400 is formed to be larger than the opening diameter of the outermost layer. In addition, the diameter of the under bump metal layer 400 is formed to be larger than the diameter of the land in the RDL 300 connected to the under bump metal layer 400.

Note that increasing the bump size is not only limited to the corner, and the bumps near the corner may be increased.

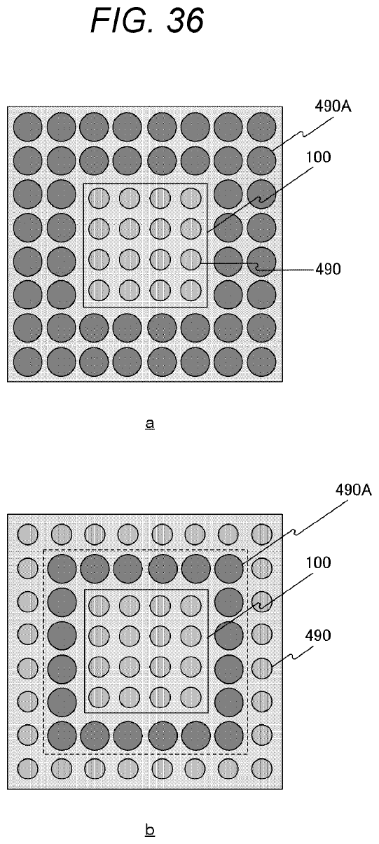

FIG. 36 is another plan view illustrating the first example of the structure of the semiconductor package according to the fifth embodiment of the present technology.

In the FOWLP, the stress increases outside the area of the built-in IC or in the bump applied to the chip edge. Therefore, as illustrated in a or b of the drawing, the bumps on the outer periphery outside the area of the IC 100 or on the chip edge may be enlarged to enhance the stress resistance.

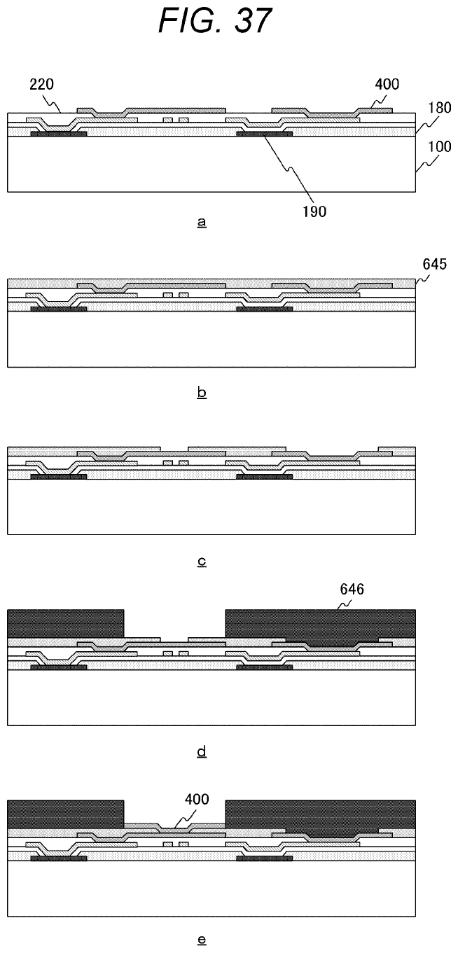

FIG. 37 is a first view illustrating an example of a bump forming process of the first example according to the fifth embodiment of the present technology.

The process is partially similar to the process of manufacturing the FOWLP of the two-layer RDL in the fifth example of the first embodiment described above, but as illustrated in a of the drawing, the under bump metal layer 400 is formed only at the position corresponding to the bumps at the corner portions when the second layer of the RDL is formed. Thereafter, a resist 645 is applied as illustrated in b of the drawing, and exposure and development are performed as illustrated in c of the drawing to open a portion of the normal bump where the under bump metal layer 400 is formed and a portion of the corner bump where the under bump metal layer 400 is formed.

Next, as illustrated in d of the drawing, a mask 646 is formed to mask a portion where the under bump metal layer 400 corresponding to a bump at a corner portion is formed, and as illustrated in e of the drawing, the under bump metal layer 400 corresponding to a normal bump is formed.

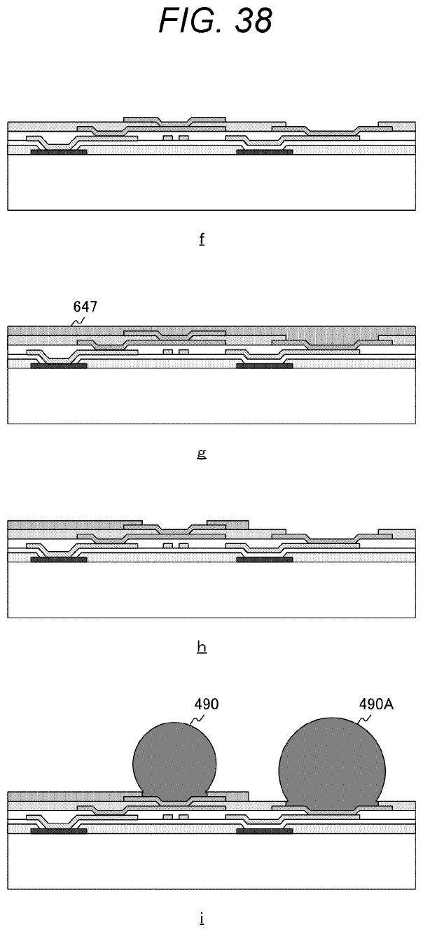

FIG. 38 is a second view illustrating an example of a bump forming process of the first example according to the fifth embodiment of the present technology.

Thereafter, according to a normal process flow, mask removal is performed as illustrated in f of the drawing, and a resist 647 is applied as illustrated in g of the drawing. Then, as illustrated in h of the drawing, a portion of the under bump metal layer 400 is opened. Then, as illustrated in i of the drawing, bumps 490 and 490A are formed by reflow after mounting the solder balls. At this time, when the solder ball is mounted, a bump 490A having a large size is used at the corner portion. At that time, the size of the ball is adjusted so that the height of the bump after reflow is aligned.

### Second Example

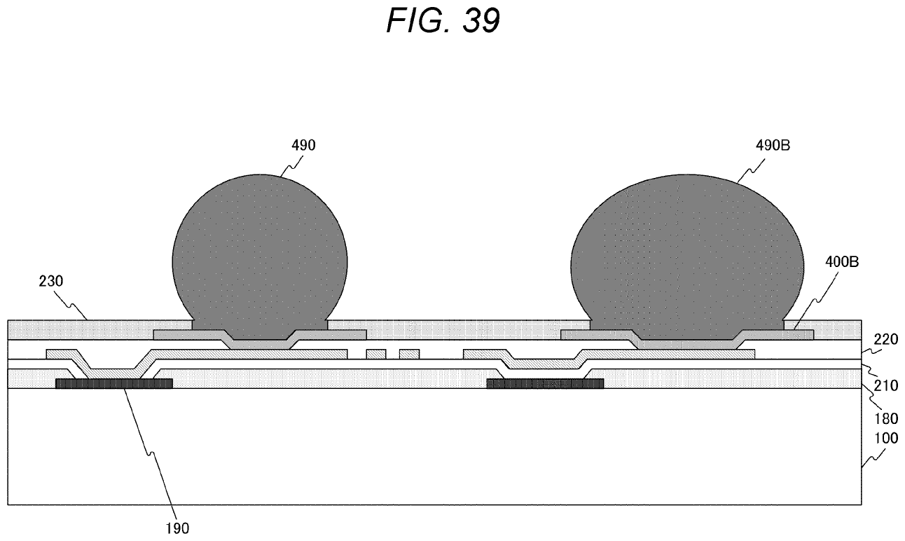

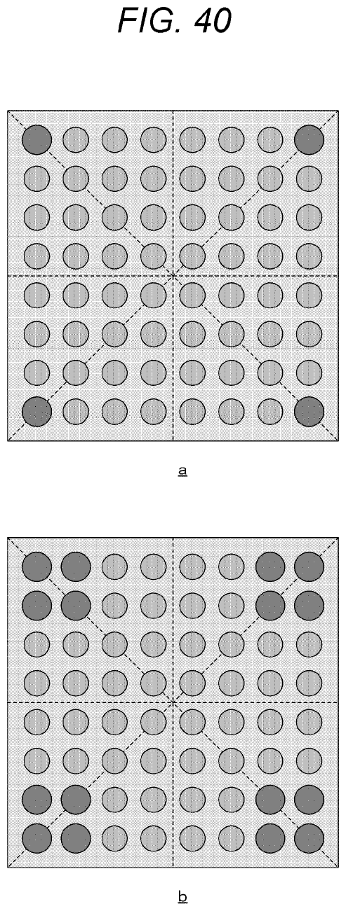

FIG. 39 is a cross-sectional view illustrating a second example of the structure of the semiconductor package according to the fifth embodiment of the present technology. FIG. 40 is a plan view illustrating the second example of the structure of the semiconductor package according to the fifth embodiment of the present technology.

The second example of the fifth embodiment has a structure in which the diameters of bumps 490B and an under bump metal layer 400B at the corner portions of the four corners to which a larger stress is applied are increased. As a result, the stress at the corner portions can be absorbed, and the stress resistance can be improved. As described above, by increasing the diameter of the under bump metal layer 400B of the corner bumps on which a larger stress is applied in the mounting reliability and there is a risk of breakage first, and also increasing the diameters of the bumps 490B, the stress resistance of the corner bumps can be enhanced. However, it is necessary to adjust the diameters of the under bump metal layer 400B and the bumps 490B to appropriate sizes in order to match the height of each bump finally formed.

Also in the second example of the fifth embodiment, similarly to the above-described first embodiment, the diameters of the under bump metal layers 400 and 400B are formed to be larger than the opening diameter of the outermost layer. In addition, the diameters of the under bump metal layers 400 and 400B are formed to be larger than the diameter of the land in the RDL 300 connected to the under bump metal layer 400 or 400B.

Note that the diameters of the under bump metal layer 400B and the bumps 490B are not only limited to the corners, and may be increased in the vicinity of the corners.

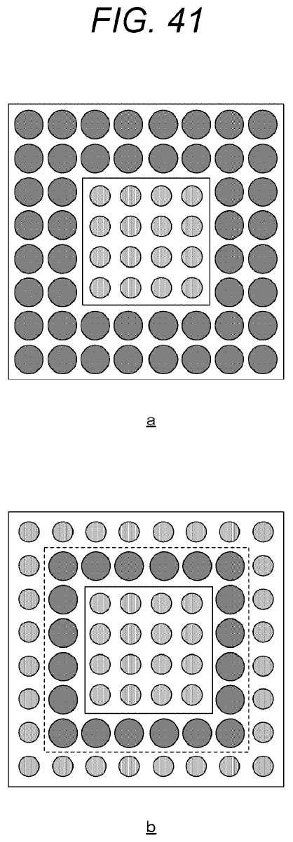

FIG. 41 is another plan view illustrating the second example of the structure of the semiconductor package according to the fifth embodiment of the present technology.

In the FOWLP, the stress increases outside the area of the built-in IC or in the bump applied to the chip edge. Therefore, as illustrated in a or b of the drawing, the bumps on the outer periphery outside the area of the IC 100 or on the chip edge may be enlarged to enhance the stress resistance.

As described above, according to the fifth embodiment of the present technology, by increasing the height or diameter of the bump in which stress is more concentrated and breakage may occur first, it is possible to enhance the stress resistance and improve the resistance of the mounting reliability as a package.

### 6. Sixth Embodiment

### First Example

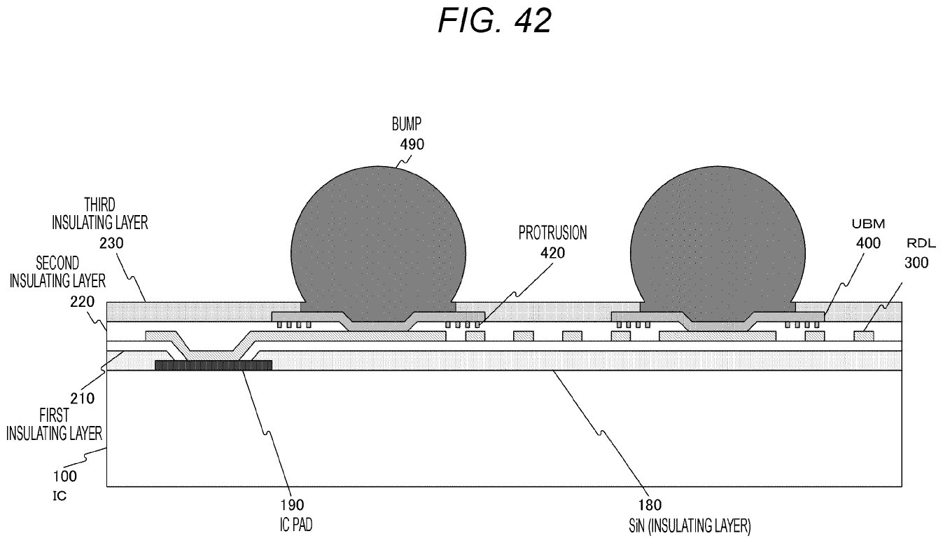

FIG. 42 is a cross-sectional view illustrating a first example of a structure of a semiconductor package according to a sixth embodiment of the present technology.

In the first example of the sixth embodiment, the under bump metal layer 400 includes a protrusion 420 at the interface with the second insulating layer 220 facing the lower portion of the under bump metal layer among the plurality of insulating layers. Consequently, the impact resistance can be improved by providing the recess in second insulating layer 220.

Also in the first example of the sixth embodiment, similarly to the above-described first embodiment, the diameter of the under bump metal layer 400 is formed to be larger than the opening diameter of the outermost layer. In addition, the diameter of the under bump metal layer 400 is formed to be larger than the diameter of the land 310 in the RDL 300 connected to the under bump metal layer 400.

### Second Example

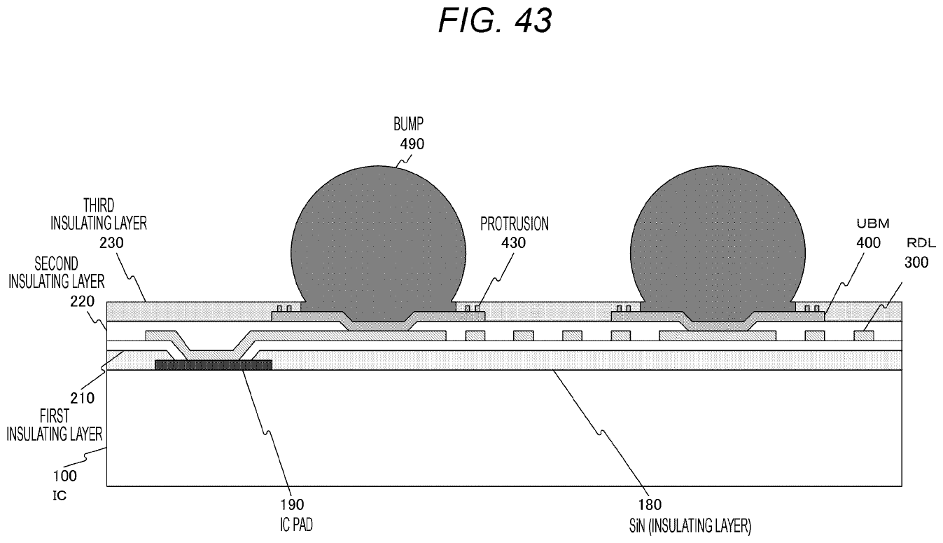

FIG. 43 is a cross-sectional view illustrating a second example of the structure of the semiconductor package according to the sixth embodiment of the present technology.

In the second example of the sixth embodiment, the under bump metal layer 400 includes a protrusion 430 at the interface with the third insulating layer 230 as the outermost layer among the plurality of insulating layers. As a result, adhesion with the third insulating layer 230 is improved, so that mounting reliability can be improved.

Also in the second example of the sixth embodiment, similarly to the above-described first embodiment, the diameter of the under bump metal layer 400 is formed to be larger than the opening diameter of the outermost layer. In addition, the diameter of the under bump metal layer 400 is formed to be larger than the diameter of the land 310 in the RDL 300 connected to the under bump metal layer 400.

As described above, according to the sixth embodiment of the present technology, by providing the protrusion at the interface with the insulating layer facing the under bump metal layer 400, impact resistance or mounting reliability can be improved.

### 7. Seventh Embodiment

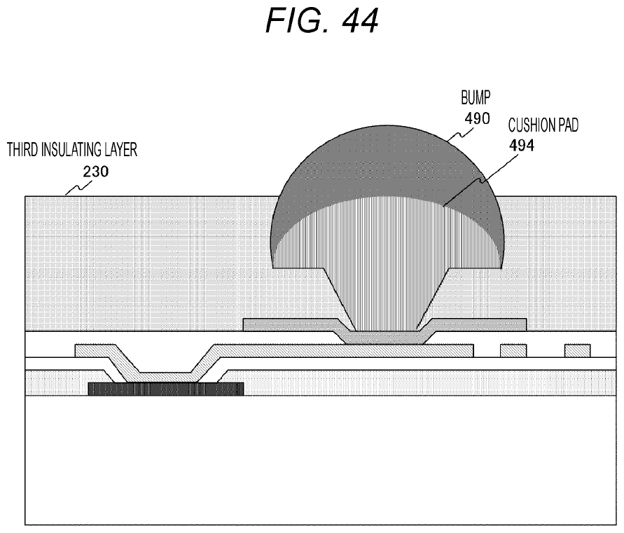

FIG. 44 is a cross-sectional view illustrating a first structural example of a semiconductor package according to a seventh embodiment of the present technology.

In the seventh embodiment, a cushion pad 494 having an overhanging shape is provided between the bump 490 and the under bump metal layer 400. The cushion pad 494 is formed by containing copper as a material, for example. With the cushion pad 494, thermal stress can be diffused to the third insulating layer 230 on the surface layer to diffuse the stress.

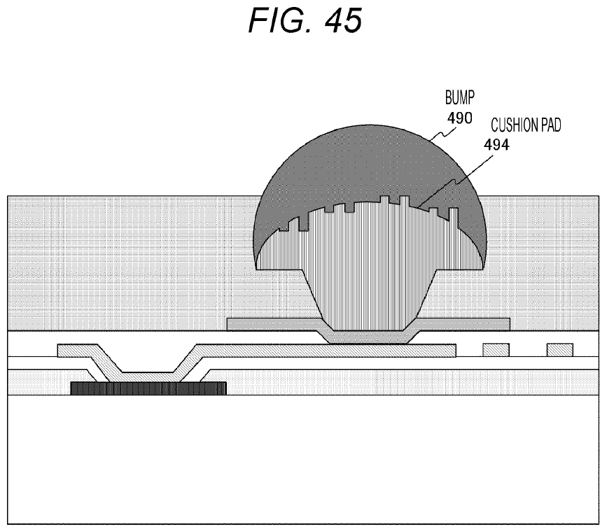

FIG. 45 is a cross-sectional view illustrating a second structural example of the semiconductor package according to the seventh embodiment of the present technology.

In the second structural example, a protrusion or a recess is provided on the surface of the cushion pad 494. As a result, adhesion between the cushion pad 494 and the bump 490 can be improved, and mounting reliability can be improved.

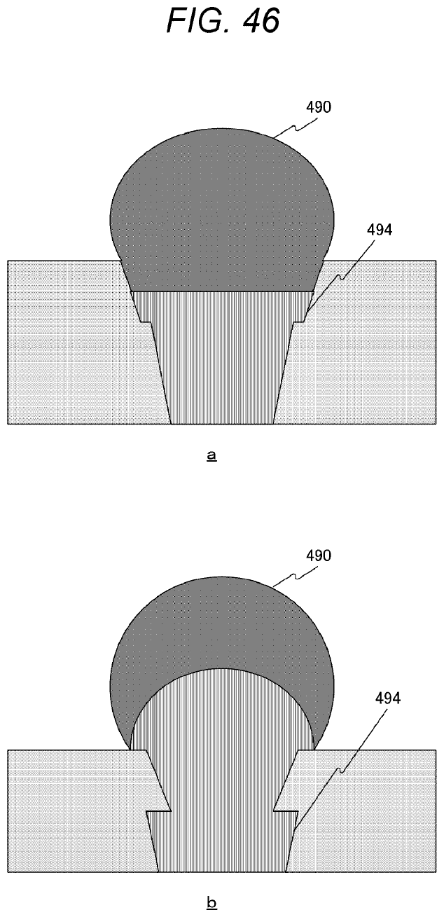

FIG. 46 is a cross-sectional view illustrating a modification of the cushion pad 494 according to the seventh embodiment of the present technology.

In the drawing, a has a structure in which a mushroom-shaped umbrella portion of the cushion pad 494 is flattened. Also in this case, since the cushion pad 494 itself has an overhanging shape, stress can be diffused.

In b of the drawing, a saw-shaped step is formed on a handle portion of the cushion pad 494. In this case, since there are more overhanging shapes, stress can be efficiently diffused.

Note that, also in the seventh embodiment, similarly to the first embodiment described above, the diameter of the under bump metal layer 400 is formed to be larger than the opening diameter of the outermost layer. In addition, the diameter of the under bump metal layer 400 is formed to be larger than the diameter of the land 310 in the RDL 300 connected to the under bump metal layer 400.

As described above, according to the seventh embodiment of the present technology, by providing the cushion pad 494 having an overhanging shape between the bump 490 and the under bump metal layer 400, thermal stress can be diffused to the third insulating layer 230 on the surface layer, and stress can be diffused.

### 8. Eighth Embodiment

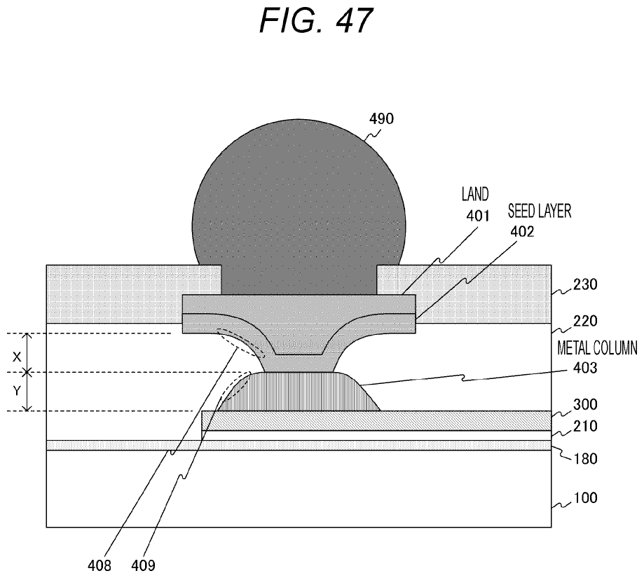

FIG. 47 is a cross-sectional view illustrating a first structural example of a semiconductor package according to an eighth embodiment of the present technology.

In the eighth embodiment, the under bump metal layer is constituted by a land 401 and a seed layer 402. The seed layer 402 is a seed layer for via embedding plating, and is a sputtered film laminate of a titanium copper alloy (Ti/Cu) or the like. The land 401 has a structure in which, for example, copper is embedded on the seed layer 402. The seed layer 402 has a tapered shape, and a side surface 408 of the cross section has a gentle curvature radius inclination. The curvature radius of the side surface 408 is desirably, for example, 10 μm or more.

In addition, in the eighth embodiment, a metal column 403 is provided between the RDL 300 and the seed layer 402. The metal column 403 is formed by, for example, copper plating. The metal column 403 has a tapered shape, and a side surface 409 of the cross section has a gentle curvature radius inclination. The curvature radius of the side surface 409 is desirably, for example, 10 μm or more.

In the first structural example, the height x of the side surface of the seed layer 402 is equal to the height y of the side surface of the metal column 403. Therefore, the structure is suitable for a case where it is necessary to equalize the stress concentration in the vertical direction.

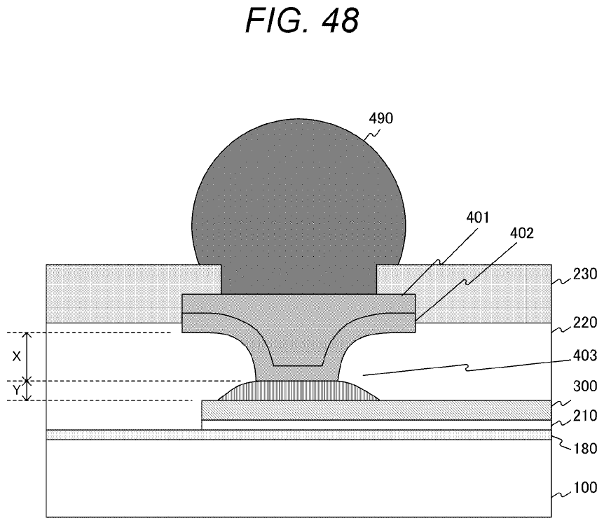

FIG. 48 is a cross-sectional view illustrating a second structural example of the semiconductor package according to the eighth embodiment of the present technology.

In the second structural example, the height x of the side surface of the seed layer 402 is higher than the height y of the side surface of the metal column 403. Therefore, the structure is suitable in a case where the stress of the lower portion needs to be smaller than the stress of the upper portion.

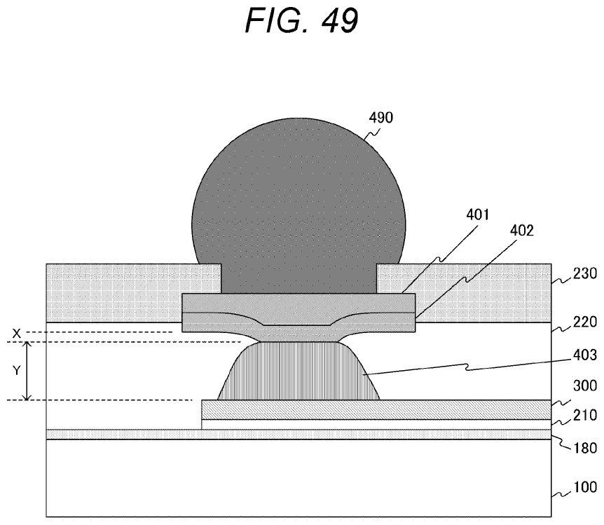

FIG. 49 is a cross-sectional view illustrating a third structural example of the semiconductor package according to the eighth embodiment of the present technology.

In the third structural example, the height x of the side surface of the seed layer 402 is lower than the height y of the side surface of the metal column 403. Therefore, the structure is suitable in a case where the stress of the upper portion needs to be smaller than the stress of the lower portion.

Also in the eighth embodiment, similarly to the first embodiment described above, the diameters of the land 401 and the seed layer 402 are formed to be larger than the opening diameter of the outermost layer. In addition, the diameters of the land 401 and the seed layer 402 are formed to be larger than the diameter of the land 310 in the RDL 300 connected to the metal column 403.

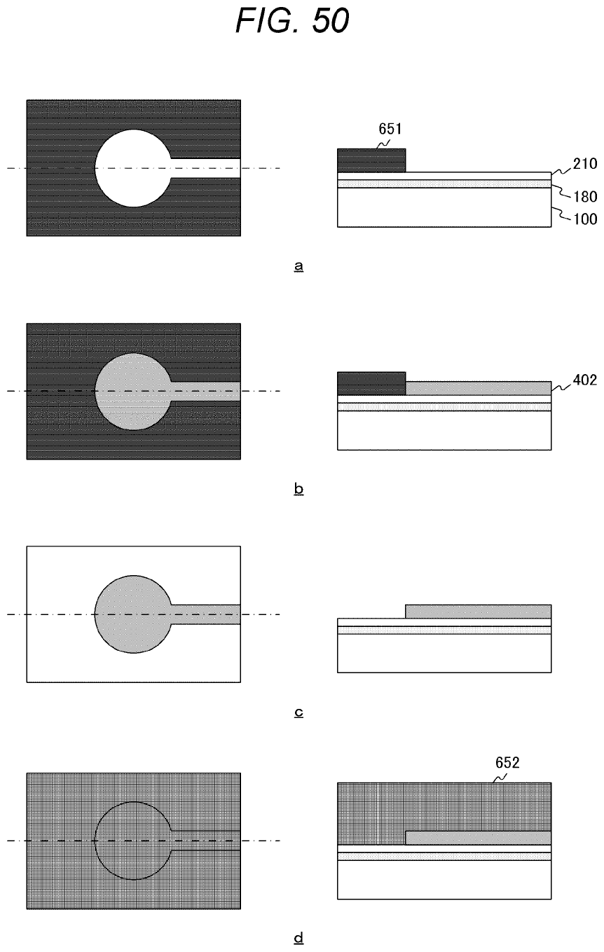

FIG. 50 is a first view illustrating a manufacturing process example of the semiconductor package according to the eighth embodiment of the present technology.

First, as illustrated in a of the drawing, the seed layer 402 is formed on the first insulating layer 210 by sputtering of a titanium copper alloy (Ti/Cu) or the like. Then, the plating resist 651 is applied, exposed, and developed to perform patterning.

Then, as illustrated in b of the drawing, copper plating is performed. In the copper plating, the thickness is increased in consideration of the film loss in the seed etching. Thereafter, the plating resist 651 is peeled off as illustrated in c of the drawing. At this time, the seed layer 402 is left.

Next, as illustrated in d of the drawing, a plating resist 652 is applied.

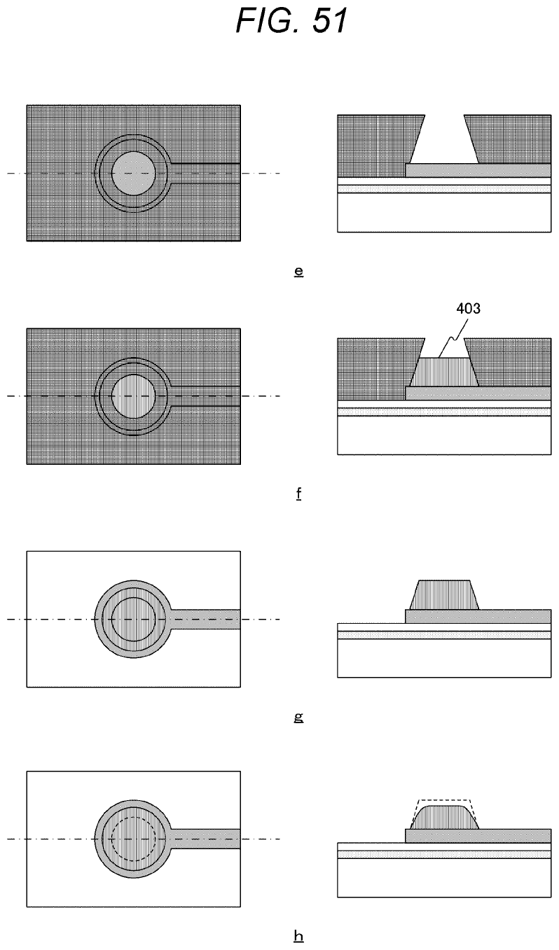

FIG. 51 is a second view illustrating a manufacturing process example of the semiconductor package according to the eighth embodiment of the present technology.

Then, as illustrated in e of the drawing, the plating resist 652 is exposed and developed. At the time of exposure, under-exposure is performed. Thus, the plating resist 652 is formed in a reverse tapered shape.

Then, as illustrated in f of the drawing, copper plating for forming the metal column 403 at the lower portion of the via is performed. At this time, the remaining seed layer 402 is reused. Then, as illustrated in g of the drawing, the plating resist 652 is peeled off.

Then, copper seed etching is performed as illustrated in h of the drawing. By performing over-etching during the copper seed etching, the corners of the trapezoid are formed to have a gentle curvature radius.

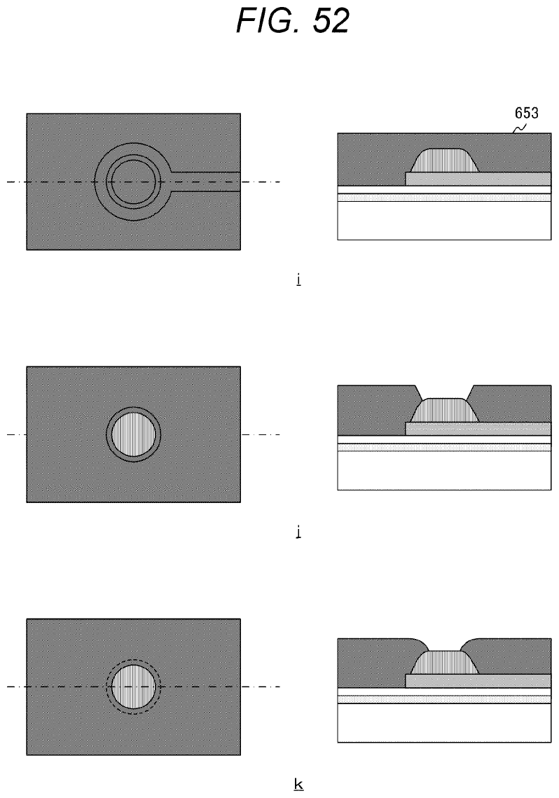

FIG. 52 is a third view illustrating a manufacturing process example of the semiconductor package according to the eighth embodiment of the present technology.

Next, as illustrated in i of the drawing, the material of the insulating layer 653 is applied. As a material of the insulating layer 653, polyimide (PI) or polybenzoxazole (PBO) can be used.

Then, as illustrated in j of the drawing, exposure and development are performed to cure the insulating layer 653 in order to open the insulating layer. However, over-development and curing at a low temperature for a long time may be performed.

Then, as illustrated in k of the drawing, the oxide film on the copper is removed. At this time, corner portions of the opening are chamfered by pre-cleaning before seed sputtering (sputter etching). Specifically, in a pre-clean chamber (reverse sputtering with argon) provided side by side in the sputtering apparatus, the surface of the copper pillar exposed from the opening and having residues of the oxide film and the insulating layer resin remaining is cleaned. Then, at the same time, the steep corner portions of the opening are also etched by this sputter etching.

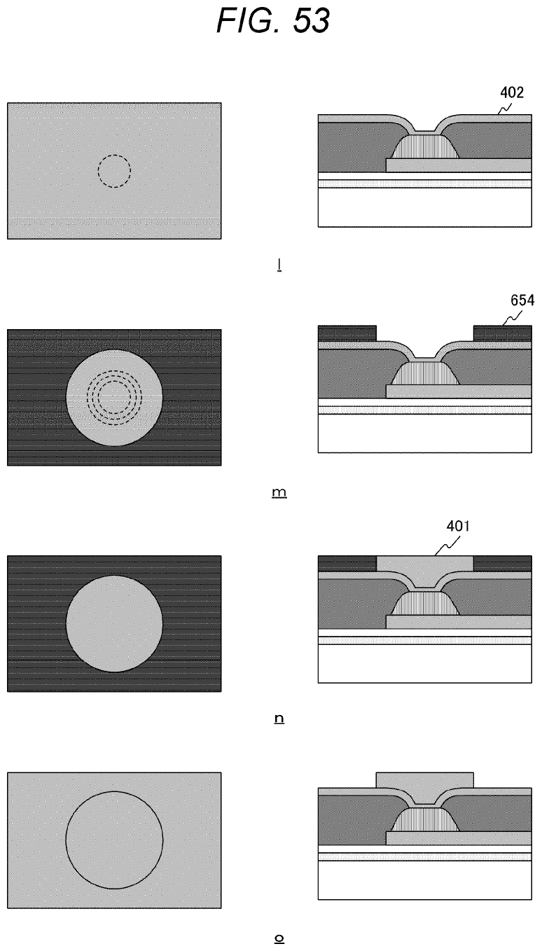

FIG. 53 is a fourth view illustrating a manufacturing process example of the semiconductor package according to the eighth embodiment of the present technology.

Next, as illustrated in 1 of the drawing, seed sputtering for forming the seed layer 402 is performed. Thus, for example, a sputtered film laminate of a titanium copper alloy (Ti/Cu) or the like is formed.

Next, an opening of the plating resist 654 is formed as illustrated in m of the drawing. That is, the plating resist 654 is applied to perform exposure and development. Then, as illustrated in n of the drawing, the land 401 is formed at the upper portion of the via by performing copper plating. Thereafter, the plating resist 654 is peeled off as illustrated in 0 of the drawing.

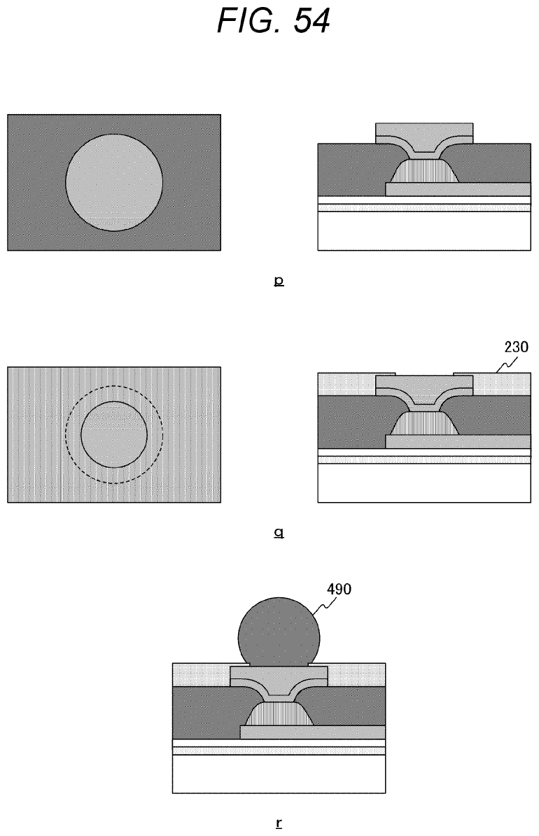

FIG. 54 is a fifth view illustrating a manufacturing process example of the semiconductor package according to the eighth embodiment of the present technology.

Next, as illustrated in p of the drawing, seed etching is performed to remove unnecessary portions of the seed layer 402. Then, as illustrated in q in the drawing, a solder resist of the third insulating layer 230 is applied, exposed and developed, and cured.

Thereafter, as illustrated in r of the drawing, the bump 490 is mounted by reflow. At that time, an unnecessary oxide film is removed, and a flux is applied.

As described above, in the eighth embodiment of the present technology, the metal column 403 having a gentle curvature radius in cross section is formed at the lower portion of the via, the seed layer 402 having a gentle curvature radius is formed at the upper portion of the via by a seed layer formation process or the like on the insulating layer opening, and the land 401 is formed by subsequent copper embedded plating. As a result, it is possible to suppress the stress concentration in the via corner portion in the substrate mounted state and to prevent the crack of the RDL 300.

### 9. Application Example

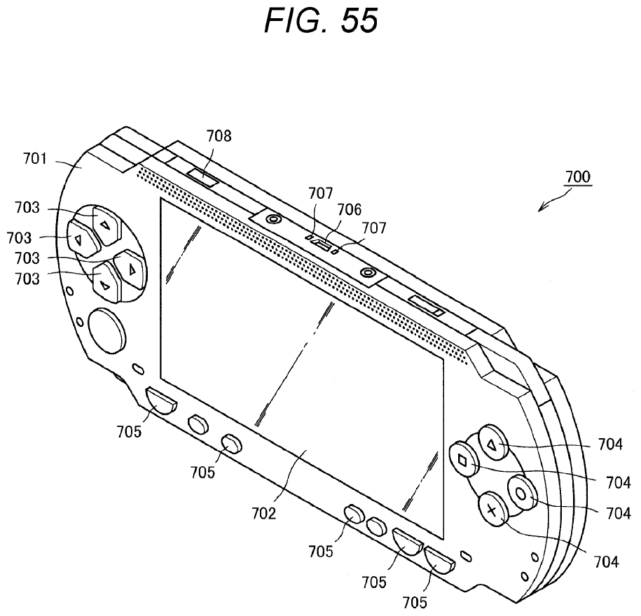

FIG. 55 is a perspective view illustrating an external configuration example of an electronic device 700 including a semiconductor package according to an embodiment of the present technology.

The electronic device 700 has, for example, an external appearance in which each component is arranged inside and outside an outer casing 701 formed in a horizontally long flat shape. The electronic device 700 may also be, for example, a device used as a game device. A display panel 702 is provided on a front surface of the outer casing 701 at the center in a longitudinal direction.

Furthermore, operation keys 703 and operation keys 704 which are arranged separately in a circumferential direction are provided on the left and right of the display panel 702. Furthermore, operation keys 705 are provided on a lower end of the front surface of the outer casing 701. The operation keys 703, 704, and 705 serve as direction keys, enter keys, or the like, and are used to select menu items displayed on the display panel 702, to advance a game and the like.

Furthermore, a connection terminal 706 for connecting an external device, a supply terminal 707 for power supply, a light receiving window 708 for performing infrared communication with an external device and the like are provided on an upper surface of the outer casing 701.

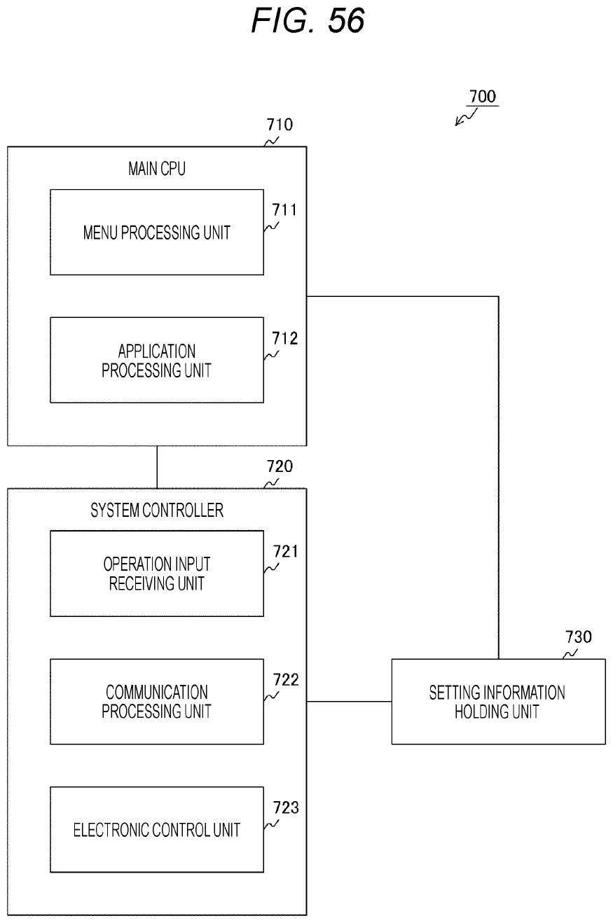

FIG. 56 is a block diagram illustrating a functional configuration example of the electronic device 700 including a semiconductor package according to an embodiment of the present technology.

The electronic device 700 is provided with a main central processing unit (CPU) 710 and a system controller 720. Power is supplied to the main CPU 710 and the system controller 720 by different systems from a battery not illustrated or the like, for example. The main CPU 710 includes a menu processing unit 711 which generates a menu screen for allowing the user to set various pieces of information or select an application, and an application processing unit 712 which executes the application.

Furthermore, the electronic device 700 includes a setting information holding unit 730 such as a memory that holds various types of information set by the user. Information set by the user is sent from the main CPU 710 to the setting information holding unit 730, and the setting information holding unit 730 holds the sent information.

The system controller 720 includes an operation input receiving unit 721, a communication processing unit 722, and a power control unit 723. The operation input receiving unit 721 detects the state of the operation keys 703, 704, and 705. Furthermore, the communication processing unit 722 performs communication processing with the external device. The power control unit 723 controls the power supplied to each unit of the electronic device 700.

Note that the semiconductor package according to the embodiment of the present technology is mounted on at least one of the main CPU 710, the system controller 720, or the setting information holding unit 730. By using the semiconductor package according to the embodiment of the present technology, the electronic device 700 can improve the drop test characteristics and the impact resistance.

Note that the above embodiments illustrate examples for embodying the present technology, and matters in the embodiments and matters specifying the invention in the claims have correspondence relationships. Similarly, the matters specifying the invention in the claims and matters having the same names in the embodiments of the present technology have correspondence relationships. However, the present technology is not limited to the embodiments and can be embodied by making various modifications to the embodiments without departing from the gist thereof.

Note that effects described in the present specification are merely examples and are not limited, and there may also be other effects.

Note that the present technology can also take the following configurations.

(1) A semiconductor package including:
a plurality of insulating layers; and
an under bump metal layer that is partially exposed at an opening of an outermost layer among the plurality of insulating layers and is connected to a bump,
in which a diameter of the under bump metal layer is larger than a diameter of the opening.

(2) The semiconductor package according to (1), further including at least one redistribution layer connected to the under bump metal layer.

(3) The semiconductor package according to (2),
in which the diameter of the under bump metal layer is larger than a diameter of a land in the redistribution layer connected to the under bump metal layer.

(4) The semiconductor package according to (2),
in which a part of the redistribution layer is disposed to overlap immediately below the under bump metal layer.

(5) The semiconductor package according to any one of (1) to (4),
in which the under bump metal layer includes a protrusion at an interface with the bump.

(6) The semiconductor package according to (5),
in which the protrusion includes a predetermined planar shape.

(7) The semiconductor package according to (5),
in which the protrusion includes a column shape having a reverse taper relative to the bump.

(8) The semiconductor package according to any one of (1) to (7), further including a resin that covers at least a part of a connection portion between a plurality of the under bump metal layer and the bump arranged two-dimensionally.

(9) The semiconductor package according to (8),
in which the resin is formed at four corners of a predetermined region.

(10) The semiconductor package according to (8),
in which the resin is formed on an outer peripheral portion of a predetermined region.

(11) The semiconductor package according to any one of (1) to (10),
in which the bump has an oval coin planar shape in at least a part of a connection portion between a plurality of the under bump metal layer and the bump arranged two-dimensionally.

(12) The semiconductor package according to (11),
in which the bump having the oval coin planar shape is formed at four corners of a predetermined region.

(13) The semiconductor package according to (11),
in which the bump having the oval coin planar shape is formed on an outer peripheral portion of a predetermined region.

(14) The semiconductor package according to (11),
in which the bump having the oval coin planar shape has an inclination that radially spreads in a predetermined region.

(15) The semiconductor package according to (11),
in which the bump further includes a metal column bump at a connection portion with the under bump metal layer.

(16) The semiconductor package according to any one of (1) to (15),
in which the bump has a height higher than that of other bumps at four corners of a predetermined region.

(17) The semiconductor package according to any one of (1) to (15),
in which the bump has a height higher than that of other bumps in an outer peripheral portion of a predetermined region.

(18) The semiconductor package according to any one of (1) to (15),
in which the bump has a diameter larger than that of other bumps at four corners of a predetermined region.

(19) The semiconductor package according to any one of (1) to (15),
in which the bump has a diameter larger than that of other bumps in an outer peripheral portion of a predetermined region.

(20) The semiconductor package according to any one of (1) to (19),
in which the under bump metal layer includes a protrusion at an interface with an insulating layer facing a lower portion of the under bump metal layer among the plurality of insulating layers.

(21) The semiconductor package according to any one of (1) to (20),
in which the under bump metal layer includes a protrusion at an interface with the outermost layer among the plurality of insulating layers.

(22) The semiconductor package according to any one of (1) to (21), further including a cushion pad having an overhanging shape between the bump and the under bump metal layer.

(23) The semiconductor package according to (22),
in which the cushion pad includes an uneven portion on a surface thereof.

(24) The semiconductor package according to any one of (1) to (23),
in which the under bump metal layer has a tapered shape having a first curvature radius.

(25) The semiconductor package according to (24), further including
a metal column connecting the under bump metal layer and the redistribution layer and having a tapered shape having a second curvature radius.

(26) An electronic device including a semiconductor package including: a plurality of insulating layers; and an under bump metal layer that is partially exposed at an opening of an outermost layer among the plurality of insulating layers and is connected to a bump, in which a diameter of the under bump metal layer is larger than a diameter of the opening.

REFERENCE SIGNS LIST

| | |
|---|---|
| 100 | IC |
| 101 | Wafer |
| 170 | Sealing resin |
| 180 | Insulating layer |
| 190 | IC pad |
| 210, 220, 230, 240 | Insulating layer |
| 300 | Redistribution layer (RDL) |
| 310 | Land |
| 390 | Copper pillar |
| 400, 400B | Under bump metal layer (UBM) |
| 401 | Land |
| 402 | Seed layer |
| 403 | Metal column |
| 410, 420, 430 | Protrusion |
| 411 | Mushroom-shaped bump |
| 412 | Metal column |
| 490, 490A, 490B | Bump |
| 491 | Solder |
| 492 | Nickel |
| 493 | Copper pillar bump |
| 494 | Cushion pad |
| 495 | Solder |
| 496 | Nickel |
| 497 | Copper |
| 498 | Liquid resin |
| 499 | Resin |
| 500 | Mounting substrate |
| 610 | Support material |
| 620, 630 | Resist |
| 641 | Metal mask |
| 642 | Squeegee |
| 643 | Barrier seed metal layer |
| 644 | Photoresist |
| 645 | Resist |
| 646 | Mask |
| 647 | Resist |
| 651, 652, 654 | Plating resist |
| 653 | Insulating layer |
| 660 | Resin print screen |
| 661 | Bump mask |
| 662 | Dicing area mask |
| 663 | Squeegee |
| 671, 672 | Mold die |
| 679 | Release film |
| 700 | Electronic device |

What is claimed is:

1. A semiconductor package, comprising:
a plurality of insulating layers; and
an under bump metal layer that is partially exposed at an opening of an outermost layer among the plurality of insulating layers and is connected to a bump,
wherein a diameter of the under bump metal layer is larger than a diameter of the opening.

2. The semiconductor package according to claim 1, further comprising at least one redistribution layer connected to the under bump metal layer.

3. The semiconductor package according to claim 2,
wherein the diameter of the under bump metal layer is larger than a diameter of a land in the redistribution layer connected to the under bump metal layer.

4. The semiconductor package according to claim 2,
wherein a part of the redistribution layer is disposed to overlap immediately below the under bump metal layer.

5. The semiconductor package according to claim 1,
wherein the under bump metal layer includes a protrusion at an interface with the bump.

6. The semiconductor package according to claim 5,
wherein the protrusion has a predetermined planar shape.

7. The semiconductor package according to claim 5,
wherein the protrusion has a column shape having a reverse taper relative to the bump.

8. The semiconductor package according to claim 1, further comprising a resin that covers at least a part of a connection portion between a plurality of the under bump metal layer and the bump arranged two-dimensionally.

9. The semiconductor package according to claim 8,
wherein the resin is formed at four corners of a predetermined region.

10. The semiconductor package according to claim 8,
wherein the resin is formed on an outer peripheral portion of a predetermined region.

11. The semiconductor package according to claim 1,
wherein the bump has an oval coin planar shape in at least a part of a connection portion between a plurality of the under bump metal layer and the bump arranged two-dimensionally.

12. The semiconductor package according to claim 11,
wherein the bump having the oval coin planar shape is formed at four corners of a predetermined region.

13. The semiconductor package according to claim 11,
wherein the bump having the oval coin planar shape is formed on an outer peripheral portion of a predetermined region.

14. The semiconductor package according to claim 11,
wherein the bump having the oval coin planar shape has an inclination that radially spreads in a predetermined region.

15. The semiconductor package according to claim 11,
wherein the bump further includes a metal column bump at a connection portion with the under bump metal layer.

16. The semiconductor package according to claim 1,
wherein the bump has a height higher than that of other bumps at four corners of a predetermined region.

17. The semiconductor package according to claim 1,
wherein the bump has a height higher than that of other bumps in an outer peripheral portion of a predetermined region.

18. The semiconductor package according to claim 1,
wherein the bump has a diameter larger than that of other bumps at four corners of a predetermined region.

19. The semiconductor package according to claim 1,
wherein the bump has a diameter larger than that of other bumps in an outer peripheral portion of a predetermined region.

20. The semiconductor package according to claim 1,
wherein the under bump metal layer includes a protrusion at an interface with an insulating layer facing a lower portion of the under bump metal layer among the plurality of insulating layers.

21. The semiconductor package according to claim 1,
wherein the under bump metal layer includes a protrusion at an interface with the outermost layer among the plurality of insulating layers.

22. The semiconductor package according to claim 1, further comprising a cushion pad having an overhanging shape between the bump and the under bump metal layer.

23. The semiconductor package according to claim 22,
wherein the cushion pad includes an uneven portion on a surface thereof.

24. The semiconductor package according to claim 1,
wherein the under bump metal layer has a tapered shape having a first curvature radius.

25. The semiconductor package according to claim 24, further comprising
a metal column connecting the under bump metal layer and the redistribution layer and having a tapered shape having a second curvature radius.

26. An electronic device comprising a semiconductor package including: a plurality of insulating layers; and an under bump metal layer that is partially exposed at an opening of an outermost layer among the plurality of insulating layers and is connected to a bump, wherein a diameter of the under bump metal layer is larger than a diameter of the opening.
